(19) United States
(12) Patent Application Publication
(10) Pub. No.: US 2026/0365905 A1
(43) Pub. Date: Nov. 19, 2026

(54) HIGH-PERFORMANCE DIELECTRIC NANOFLUID

(71) Applicant: Brian Marcuzzo, Mobile, AL (US)

(72) Inventor: Brian Marcuzzo, Mobile, AL (US)

(21) Appl. No.: 19/679,582

(22) Filed: May 15, 2026

Related U.S. Application Data
(60) Provisional application No. 63/806,192, filed on May 15, 2025.

(51) Int. Cl. C09K 5/14; G06F 1/20; H05K 7/20

(52) U.S. Cl. CPC C09K 5/14; G06F 1/206; H05K 7/20254; H05K 7/20272; H05K 7/20772; G06F 2200/201

(57) ABSTRACT

A high-performance dielectric nanofluid for electronic cooling is provided. The high-performance dielectric nanofluid comprises a base fluid, nanoparticles dispersed within the base fluid, and at least one additive. The nanofluid exhibits a thermal conductivity of at least about 1.0 W/m·K, a dielectric strength of at least about 15 kV/mm, and an electrical conductivity of less than about 1×10⁻⁹ S/m. A method of manufacturing the nanofluid includes preparing a pre-dispersion of nanoparticles in a base fluid, combining the pre-dispersion with a base fluid mixture in a continuous-flow microfluidic device, subjecting the combined mixture to in-line ultrasonic treatment, and introducing additives. A cooling system for electronic components utilizes the nanofluid circulating through cold plates in thermal contact with heat-generating components.

### CROSS-REFERENCE TO RELATED APPLICATIONS

This application claims the benefit of U.S. Provisional Application Ser. No. 63/806,192, filed on May 15, 2025, which is incorporated herein in its entirety by reference.

### FIELD OF INVENTION

The present disclosure relates to a high-performance dielectric nanofluid designed for direct-to-chip cooling in data centers and other high-density computing environments.

### BACKGROUND

Data centers and high-performance computing environments face increasing challenges in managing thermal loads generated by densely packed electronic components. As processing power continues to grow exponentially, traditional air-cooling methods struggle to efficiently dissipate heat from modern high-density server racks and chips. This thermal management bottleneck limits the ability to further increase computing performance and energy efficiency in data centers. Additionally, air cooling systems require significant infrastructure and energy consumption for fans, air handling units, and cooling towers, contributing substantially to data center operating costs and environmental impact. These limitations have spurred research into more effective cooling technologies that can handle higher heat fluxes while reducing energy usage and physical footprint.

Liquid cooling has emerged as a promising alternative to address the thermal management challenges in high-performance computing. By leveraging the superior heat transfer properties of liquids compared to air, liquid cooling systems can potentially remove heat more efficiently from electronic components. However, implementing liquid cooling introduces new engineering hurdles related to fluid containment, electrical isolation, and material compatibility. Many conventional coolants used in industrial applications are electrically conductive, posing risks of short circuits and component damage if leaks occur. Non-conductive fluids like mineral oils and synthetic dielectric coolants often suffer from poor thermal conductivity, limiting their heat removal capacity. Furthermore, the viscosity and flow characteristics of liquid coolants can impact pumping power requirements and fluid distribution within complex server architectures. Balancing thermal performance, electrical safety, and system reliability remains an ongoing challenge for liquid cooling implementations in mission-critical computing environments.

Beyond thermal management, data center operators face additional operational concerns related to cooling system maintenance, longevity, and environmental impact. Frequent coolant replacement due to degradation or contamination increases costs and system downtime. Some cooling fluids may pose environmental or health hazards if leaked or improperly disposed of at end-of-life. There are also challenges in designing cooling systems that can adapt to the dynamic thermal loads of modern data centers, where workloads and heat generation can fluctuate rapidly across different zones. Ideally, next generation cooling solutions should offer improved thermal performance while also addressing concerns around safety, reliability, sustainability, and operational flexibility.

Accordingly, there is a need in the art for a high-performance dielectric nanofluid designed specifically for direct-to-chip cooling applications.

### SUMMARY

A high-performance dielectric nanofluid for electronic cooling is provided. In one aspect, the nanofluid leverages engineered nanoparticles suspended in a dielectric base fluid to address the challenge of heat dissipation in high-density computing environments, a persistent problem that limits the effectiveness of traditional cooling techniques when using advanced electronic systems. In another aspect, the nanofluid uses carefully selected additives to enhance thermal conductivity while maintaining electrical insulation properties. In another aspect, the nanofluid is designed to integrate with existing cooling systems and electronic components in a way that requires minimal modification of said existing equipment. Generally, the nanofluid is designed to enhance existing cooling setups in a way that allows for improved heat transfer and thermal management using direct-to-chip cooling while preserving the reliability and performance of electronic systems.

The present disclosure provides a dielectric nanofluid that may be configured to provide thermal management for electronic systems. The nanofluid can comprise a silicone-based base fluid with thermally conductive nanoparticles suspended therein. In some instances, the base fluid may comprise dimethylpolysiloxane having viscosity characteristics suitable for circulation through cooling systems. The nanofluid may be configured to achieve enhanced thermal conductivity while maintaining dielectric properties that permit direct contact with electronic components. Optionally, the nanofluid can include one or more additives that contribute to dispersion stability and long-term performance. Alternatively, the formulation can be adjusted to accommodate different operating conditions and system configurations.

The nanofluid may incorporate nanoparticles that can enhance heat transfer characteristics of the base fluid. In some instances, the nanoparticles may comprise hexagonal boron nitride, which can provide favorable thermal properties while maintaining electrical insulation characteristics. The nanoparticles may be configured to remain suspended within the base fluid through the use of dispersants and surface treatments. Optionally, the nanoparticles can undergo functionalization processes to improve compatibility with the base fluid. The concentration of nanoparticles may be selected to balance thermal performance with fluid handling characteristics. Alternatively, different nanoparticle types or combinations can be employed depending on the intended application.

The nanofluid formulation may include additives that can contribute to operational performance and stability over time. In some instances, a dispersant may be configured to provide steric stabilization of the suspended nanoparticles within the base fluid. An anti-foam agent can optionally be incorporated to address bubble formation that may occur during fluid circulation. Thermal stabilizers may be included to help maintain fluid properties across a range of operating temperatures. Alternatively, corrosion inhibitors can be added to provide protection for system components that contact the nanofluid. The nanofluid may be configured to operate within cooling systems designed for high-density computing environments and other electronic applications where thermal management can be beneficial.

The foregoing summary has outlined some features of the system and method so that those skilled in the pertinent art may better understand the detailed description that follows. Additional features that form the subject of the claims will be described hereinafter. Those skilled in the pertinent art should appreciate that they can readily utilize these features for designing or modifying other systems for carrying out the same purpose of the system and method disclosed herein. Those skilled in the pertinent art should also realize that such equivalent designs or modifications do not depart from the scope of the system and method.

### BRIEF DESCRIPTION OF FIGURES

These and other features, aspects, and advantages will become better understood with regard to the following description, appended claims, and accompanying drawings where:

FIG. 1 illustrates a schematic diagram of high-performance dielectric nanofluid composition, according to aspects.

FIG. 2 illustrates a cooling system for data center applications utilizing a PDMS-based nanofluid coolant, according to aspects.

FIG. 3 illustrates a flowchart depicting a method for mixing a thermal management fluid, according to an embodiment.

FIG. 4 illustrates a manufacturing process flow diagram for high-performance dielectric nanofluid production, in accordance with example embodiments.

### DETAILED DESCRIPTION

In the Summary above and in this Detailed Description, and the claims below, and in the accompanying drawings, reference is made to particular features, including method steps, of the invention. It is to be understood that the disclosure of the invention in this specification includes all possible combinations of such particular features. For instance, where a particular feature is disclosed in the context of a particular aspect or embodiment of the invention, or a particular claim, that feature can also be used, to the extent possible, in combination with/or in the context of other particular aspects of the embodiments of the invention, and in the invention generally.

The term “comprises” and grammatical equivalents thereof are used herein to mean that other components, steps, etc. are optionally present. For instance, a system “comprising” components A, B, and C can contain only components A, B, and C, or can contain not only components A, B, and C, but also one or more other components. The phrase “at least one of A and B” is used herein to mean “only A, only B, or both A and B.” The phrase “at least one of A or B” is used herein to mean “only A or only B but not both A and B” Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility). As will be evident from the disclosure provided below, the present invention satisfies the need for a high-performance dielectric nanofluid designed specifically for direct-to-chip cooling applications.

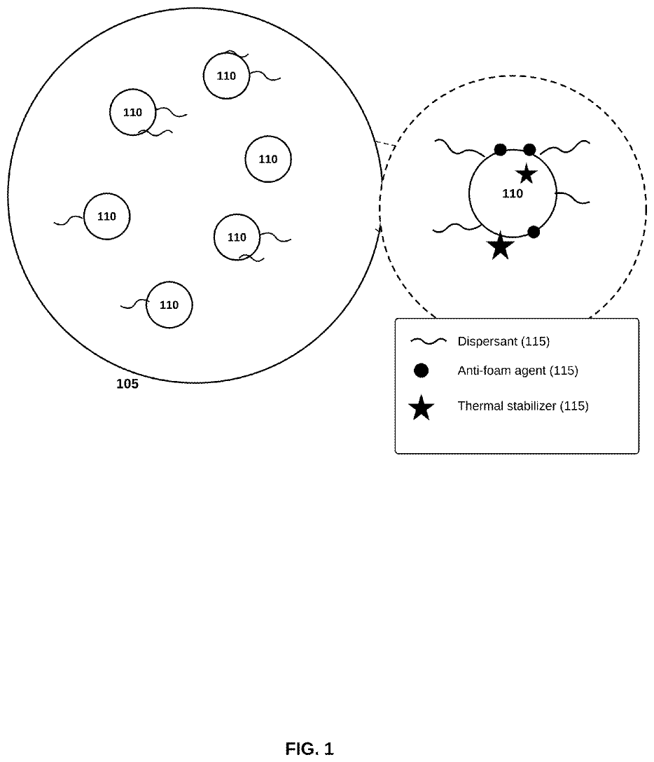

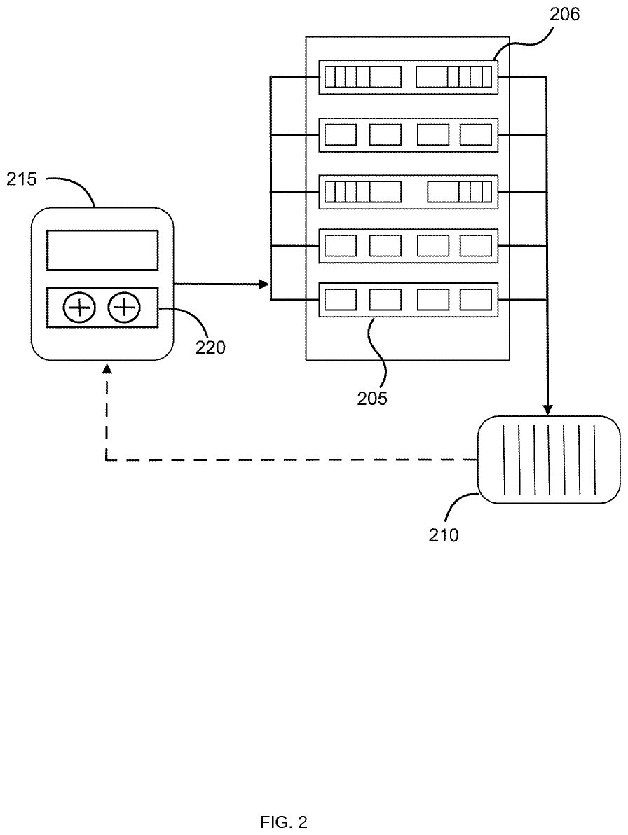

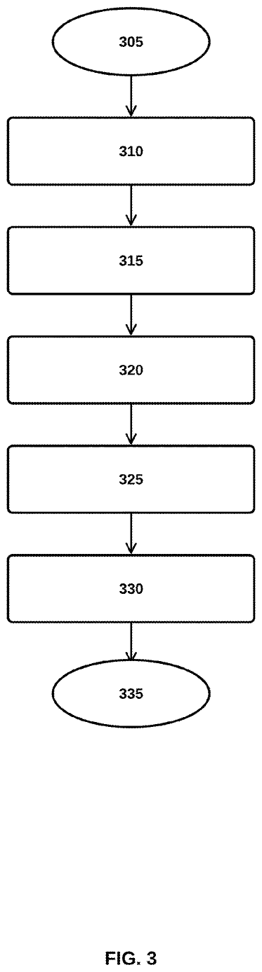

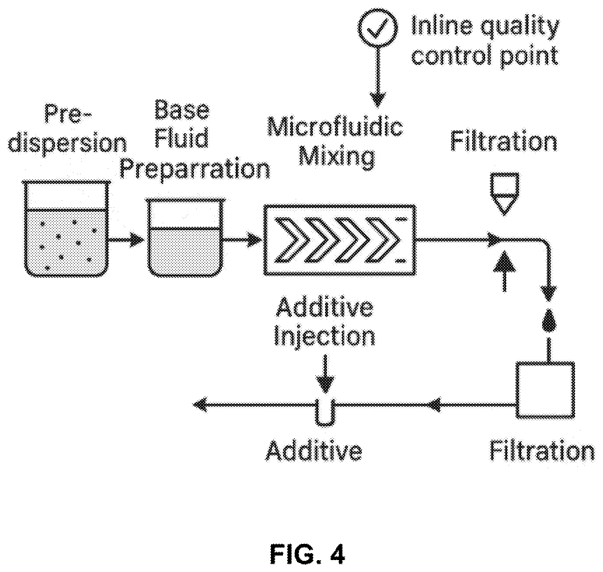

FIGS. 1-4 illustrate embodiments of a system and methods for high-performance dielectric nanofluid cooling in electronic systems. FIG. 1 illustrates a schematic diagram of the high-performance dielectric nanofluid composition, showing the arrangement of nanoparticles 110, dispersant, and other additives within the base fluid 105. FIG. 2 shows a diagram of a cooling system 215 for data center applications utilizing the PDMS-based nanofluid coolant, including server racks 205 with cold plates 206, a coolant distribution unit, and heat exchangers 210. FIG. 3 illustrates a method for mixing the thermal management fluid, showing the sequence of steps involved in preparing the nanofluid. FIG. 4 depicts a manufacturing process flow diagram for high-performance dielectric nanofluid production, including steps for pre-dispersion, base fluid preparation, microfluidic mixing, and filtration. It is understood that the various method steps associated with the methods may be carried out as operations by the cooling system 215 shown in FIGS. 1 and 2.

The dielectric nanofluid that may be configured to provide thermal management for electronic systems in high-density computing environments. The dielectric nanofluid can comprise a base fluid 105 and nanoparticles 110 dispersed therein, where the base fluid 105 serves as a carrier medium for the suspended nanoparticles 110 and additives. In a preferred embodiment, the base fluid 105 comprises a silicone-based polymer, and in some preferred embodiments, the base fluid 105 comprises polydimethylsiloxane (PDMS), also referred to as dimethylpolysiloxane, where these terms are used interchangeably throughout the present disclosure to refer to the same class of linear silicone polymer consistent with standard industry practice. As illustrated in FIG. 1, the base fluid 105 comprises PDMS, which provides a matrix within which the nanoparticles 110, dispersant, anti-foam agent, and thermal stabilizer components are distributed. Alternatively, other dielectric base fluids may be employed depending on the specific application requirements, including but not limited to other silicone fluids, fluorinated fluids, or hydrocarbon-based dielectric fluids that exhibit suitable thermal and electrical properties. The selection of the base fluid 105 can influence the overall thermal performance, electrical insulation characteristics, and long-term stability of the dielectric nanofluid formulation.

In a preferred embodiment, the base fluid 105 may be configured to have a kinematic viscosity at 25 °C in the range of from about 50 cSt to about 1000 cSt, which can encompass a broad range of commercially available grades suitable for electronic cooling applications. In some preferred embodiments, the PDMS can have a kinematic viscosity at 25 °C in the range of from about 100 cSt to about 500 cSt, which may provide a balance between heat transfer efficiency and pumping power requirements in cooling system 215 configurations. In another preferred embodiment, the PDMS may have a kinematic viscosity at 25 °C in the range of from about 100 cSt to about 150 cSt, which can facilitate flow characteristics suitable for circulation through cold plates 206 and microchannels in cooling systems 215 as illustrated in FIG. 2. In some instances, lower viscosity grades within these ranges may be selected for applications where reduced pumping energy consumption is desired, such as large-scale data center installations where cumulative pumping power can represent a significant operational cost. Alternatively, higher viscosity grades may be employed in applications where enhanced film formation, reduced leakage potential, or improved lubrication of pump components is beneficial. The viscosity characteristics of the base fluid 105 can influence the overall thermal performance, pressure drop through the cooling circuit, and system efficiency of the cooling solution, and the selection of an appropriate viscosity grade or range may depend on factors including cold plate geometry, tubing diameter, pump capacity, and the anticipated operating temperature range.

In some preferred embodiments, the base fluid 105 may comprise a single-grade PDMS, or alternatively, a blend of two or more PDMS grades having different kinematic viscosities to achieve targeted rheological properties for electronic cooling applications. In a preferred embodiment, the base fluid 105 can comprise a blend of a first PDMS grade having a kinematic viscosity of from about 10 cSt to about 100 cSt and a second PDMS grade having a kinematic viscosity of from about 100 cSt to about 1000 cSt, where the proportions of each grade may be configured to produce a target kinematic viscosity within the ranges set forth herein. By way of non-limiting example, a blend comprising approximately 30% by weight of a 20 cSt PDMS grade and approximately 70% by weight of a 200 cSt PDMS grade may yield a target viscosity suitable for data center cooling applications where flow through cold plates 206 and microchannels is a consideration. In another preferred embodiment, a blend comprising approximately 50% by weight of a 50 cSt PDMS grade and approximately 50% by weight of a 150 cSt PDMS grade may be employed to achieve intermediate viscosity characteristics for applications where both heat transfer efficiency and pumping power consumption are factors. The blending approach can provide flexibility in tailoring the rheological properties of the base fluid 105 to specific system configurations, including variations in cold plate geometry, tubing diameter, and pump capacity. Optionally, three or more PDMS grades may be combined to achieve finer control over the viscosity profile and temperature-dependent flow behavior of the nanofluid, such as a ternary blend comprising a low-viscosity grade of approximately 10 cSt, a medium-viscosity grade of approximately 100 cSt, and a high-viscosity grade of approximately 500 cSt in proportions selected to optimize performance across the anticipated operating temperature range.

Commercial PDMS grades suitable for use in the present disclosure may include, by way of non-limiting example, grades available from Dow (such as Xiameter PMX-200 silicone fluid series in viscosity grades ranging from 5 cSt to 1000 cSt), Gelest (such as DMS silicone fluids), Momentive Performance Materials (such as SF96 silicone fluids), and Shin-Etsu Chemical (such as KF-96 silicone fluids). In a preferred embodiment, the PDMS may be selected from grades that have been characterized for thermal stability and dielectric performance in electronic cooling applications, with technical data sheets providing information on properties including kinematic viscosity, pour point, flash point, and dielectric strength. In some instances, the PDMS grade may be configured to provide a pour point below approximately −40 °C to accommodate cold-climate installations or cold-start conditions, where low-viscosity grades having kinematic viscosities of approximately 5 cSt to approximately 50 cSt at 25 °C typically exhibit pour points below approximately −55 °C. Alternatively, PDMS grades with enhanced thermal stability at elevated temperatures may be selected for high-power computing applications where sustained operation above 100 °C is anticipated, and in such instances, medium-viscosity to high-viscosity grades may be preferred due to their reduced volatility at elevated temperatures. The selection of specific PDMS grades or blends can depend on factors including the intended operating temperature range, compatibility with system materials such as seals and gaskets, and desired flow characteristics through the cooling circuit including pressure drop and flow distribution uniformity. As illustrated in FIG. 2, the base fluid 105 circulates through the cooling system 215, entering cold plates 206 at approximately 35 °C and exiting at approximately 50 °C after absorbing heat from electronic components, where the viscosity characteristics of the base fluid 105 can influence the flow rate achievable at a given pump pressure and the resulting heat transfer coefficient at the cold plate surfaces.

In a preferred embodiment, PDMS is used as the base fluid 105 due to several physical and chemical properties that may contribute to favorable performance in electronic cooling applications. The thermal stability of PDMS may enable consistent performance across a wide range of operating temperatures, making it suitable for diverse electronic cooling scenarios where temperature fluctuations can occur rapidly during workload transitions or system startup and shutdown cycles. The low chemical reactivity of PDMS may contribute to the long-term stability of the nanofluid, potentially reducing the risk of degradation or unwanted interactions with system components such as metallic cold plates 206, polymeric tubing, and elastomeric seals over extended periods of operation. In a preferred embodiment, the dielectric properties of PDMS make it a suitable carrier for the nanoparticles 110 and other additives in the formulation, where the electrical insulation characteristic can be beneficial in direct-to-chip cooling applications in which the fluid may come into close contact with live electronic components operating at voltages of from about 1 V to about 48 V or higher. In some instances, the combination of thermal stability, chemical inertness, and dielectric strength positions PDMS as a foundation for the dielectric nanofluid that may enable effective heat management while maintaining the safety and integrity of the electronic systems being cooled. By leveraging the properties of PDMS, the nanofluid may offer a versatile and reliable cooling solution for a range of electronic applications, from data centers housing thousands of servers to high-performance computing environments with concentrated thermal loads exceeding 500 W per processor.

In another preferred embodiment, the base fluid 105 may be configured to exhibit specific temperature-dependent viscosity characteristics that can influence the performance of the nanofluid across the operating temperature range of the cooling system 215. The kinematic viscosity of PDMS typically decreases with increasing temperature, following an approximately exponential relationship that can be characterized by the viscosity-temperature coefficient for a given PDMS grade. In some instances, this temperature-dependent behavior may be advantageous in cooling applications, as the reduced viscosity at elevated temperatures can facilitate increased flow rates and improved heat transfer in regions of the cooling circuit where the nanofluid has absorbed thermal energy from electronic components. By way of non-limiting example, a PDMS grade having a kinematic viscosity of approximately 100 cSt at 25 °C may exhibit a kinematic viscosity of approximately 30 cSt to approximately 50 cSt at 50 °C, depending on the specific molecular weight distribution and chemical structure of the polymer. The selection of PDMS grades or blends may be configured to optimize the viscosity-temperature profile for the anticipated operating conditions, balancing considerations such as cold-start pumpability, steady-state flow characteristics, and high-temperature stability. Optionally, the viscosity-temperature behavior of the base fluid 105 may be characterized using rheological measurements at multiple temperatures to verify that the nanofluid formulation meets specifications for the intended cooling application.

In a preferred embodiment, the dielectric nanofluid comprises nanoparticles 110 dispersed within the base fluid 105 to enhance the thermal transport characteristics of the formulation. The nanoparticles 110 may be configured to provide increased thermal conductivity compared to the base fluid 105 alone while maintaining the dielectric properties suitable for electronic cooling applications. In some preferred embodiments, the nanoparticles 110 comprise thermally conductive ceramic materials, metal oxides, nitrides, carbides, or combinations thereof that can contribute to heat transfer enhancement without compromising electrical insulation characteristics. The selection of nanoparticle material may depend on factors including thermal conductivity, electrical resistivity, chemical compatibility with the base fluid 105, and availability in appropriate particle size distributions. Alternatively, the nanoparticles 110 may comprise carbon-based materials such as graphene or carbon nanotubes in applications where the electrical conductivity of these materials can be tolerated or where surface treatments have been applied to reduce conductivity. In some instances, hybrid nanoparticle systems comprising two or more different nanoparticle types may be employed to achieve synergistic thermal enhancement effects or to balance multiple performance characteristics within the nanofluid formulation.

In another preferred embodiment, the nanoparticles 110 comprise hexagonal boron nitride (hBN), which may be suspended within the base fluid 105 to form a stable dispersion suitable for circulation through electronic cooling systems. As illustrated in FIG. 1, the hBN nanoparticles may be distributed throughout the base fluid 105 along with the dispersant, anti-foam agent, and thermal stabilizer components to create a composite thermal management fluid. The present disclosure provides for the use of hBN nanoparticles due to their favorable combination of high thermal conductivity and electrical insulation properties, which can enable the nanofluid to efficiently transfer heat while maintaining dielectric characteristics suitable for direct contact with electronic components operating at voltages of from about 1 V to about 48 V or higher. In some preferred embodiments, the hBN nanoparticles may be configured to be selected for size, shape, and surface characteristics to optimize dispersion stability and thermal transport within the nanofluid formulation for specific cooling applications. The hBN nanoparticles can exhibit anisotropic thermal conductivity, with in-plane thermal conductivity values reported in the literature as ranging from approximately 200 W/m·K to approximately 400 W/m·K, which may contribute to the enhanced heat transfer capabilities of the nanofluid when the platelets are oriented favorably within the flowing fluid. In some instances, the incorporation of hBN nanoparticles into the base fluid 105 may result in a composite material that can leverage the thermal properties of both components to achieve improved cooling performance compared to the base fluid 105 alone, with thermal conductivity enhancements that scale with nanoparticle loading within the concentration ranges disclosed herein.

In some preferred embodiments, the hBN nanoparticles may be present at a concentration of at least about 20% w/w of the dielectric nanofluid, which can provide a baseline level of thermal enhancement while maintaining acceptable fluid handling characteristics for circulation through cold plates 206 and microchannels in cooling systems as illustrated in FIG. 2. In some instances, the hBN nanoparticles may be present at a concentration of from about 25% w/w to about 55% w/w, which can offer a range of thermal performance options depending on the specific application requirements and the viscosity constraints of the cooling system 215. In a preferred embodiment, the hBN nanoparticles may be present at a concentration of from about 35% w/w to about 45% w/w, which can provide a balance between enhanced thermal conductivity and manageable viscosity for circulation through cooling systems at flow rates in the range of from about 0.5 liters per minute to about 50 liters per minute per cold plate. In another preferred embodiment, the hBN nanoparticles may be present at a concentration of about 40% w/w, which can represent an optimized loading level for data center cooling applications where both thermal performance and pumping efficiency are considerations. The concentration of hBN nanoparticles may be adjusted based on factors including the desired thermal conductivity enhancement, the viscosity constraints of the cooling system 215, the pump capacity, and the specific heat dissipation requirements of the electronic components being cooled. Alternatively, lower concentrations of hBN nanoparticles within the range of from about 20% w/w to about 35% w/w may be employed in applications where reduced viscosity is prioritized, while higher concentrations within the range of from about 45% w/w to about 55% w/w may be selected for applications where maximum thermal conductivity is desired and the cooling system 215 can accommodate the associated increase in fluid viscosity.

The particle size of the hBN nanoparticles may be configured to influence both the dispersion stability and the thermal transport characteristics of the nanofluid formulation. In some preferred embodiments, the hBN nanoparticles may have a primary particle size in the range of from about 50 nm to about 1000 nm, which can encompass a broad range of commercially available hBN grades suitable for nanofluid applications in electronic cooling systems. In a preferred embodiment, the hBN nanoparticles may have a primary particle size in the range of from about 50 nm to about 500 nm, which can provide favorable surface area to volume ratios for thermal transport while maintaining reasonable dispersion stability over storage periods of from about 6 months to about 5 years. In another preferred embodiment, the hBN nanoparticles may have a primary particle size in the range of from about 100 nm to about 250 nm, which can represent an optimized size range for balancing thermal conductivity enhancement with long-term suspension stability in the base fluid 105 during circulation through cooling systems. In some instances, smaller particle sizes within these ranges may be selected to maximize the interfacial area between the nanoparticles 110 and the base fluid 105, potentially enhancing heat transfer at the particle-fluid interface through increased phonon coupling. Alternatively, larger particle sizes within the disclosed ranges may be employed in applications where reduced surface energy and improved settling resistance are desired, or where the cooling system geometry including cold plate channel dimensions in the range of from about 0.1 mm to about 10 mm can accommodate larger particles without risk of clogging or flow restriction.

The morphology of the nanoparticles 110 dispersed within the base fluid 105 can influence the thermal and rheological properties of the dielectric nanofluid formulation. In a preferred embodiment, the nanoparticles 110 may comprise hexagonal boron nitride (hBN) having a platelet morphology, which can provide favorable thermal transport characteristics due to the anisotropic crystal structure of the material. The platelet morphology may be characterized by an aspect ratio, defined as the lateral dimension divided by the thickness of the particle, which can range from about 2 to about 100 in some embodiments suitable for electronic cooling applications. In some preferred embodiments, the hBN nanoparticles may have an aspect ratio in the range of from about 5 to about 50, which can offer a balance between the enhanced thermal conductivity associated with high-aspect-ratio platelets and the improved dispersion stability associated with more equiaxed particles within the base fluid 105. In another preferred embodiment, the hBN nanoparticles may have an aspect ratio in the range of from about 10 to about 30, which can represent an optimized morphology for achieving both favorable thermal transport and acceptable rheological behavior in the nanofluid during circulation through cooling systems as illustrated in FIG. 2. The selection of nanoparticle aspect ratio may depend on factors including the target thermal conductivity enhancement, the viscosity constraints of the cooling system 215, and the long-term dispersion stability requirements for the intended application.

In some instances, the platelet morphology of hBN nanoparticles may contribute to anisotropic thermal conductivity enhancement within the dielectric nanofluid, where heat transfer can be more efficient in directions parallel to the platelet faces compared to directions perpendicular to the platelet surfaces. The orientation of hBN platelets within the flowing nanofluid may influence the effective thermal conductivity of the suspension, with shear-induced alignment potentially affecting heat transfer characteristics during circulation through cold plates 206 and microchannels in cooling systems. As illustrated in FIG. 1, the hBN nanoparticles may be distributed throughout the base fluid 105 along with the dispersant, anti-foam agent, and thermal stabilizer components, where the platelet morphology can affect the interactions between adjacent particles and the surrounding fluid matrix. In a preferred embodiment, the dispersant molecules can adsorb onto the surfaces of the hBN platelets and extend polymer chains into the surrounding PDMS medium, creating a steric barrier that maintains separation between individual particles regardless of their orientation within the fluid. In some preferred embodiments, the aspect ratio of the hBN nanoparticles may be configured to be in the range of from about 5 to about 50 as recited in claim 7, which can provide favorable thermal enhancement while maintaining acceptable flow characteristics through the cooling circuit. Optionally, hBN nanoparticles with different aspect ratios may be blended to achieve tailored rheological and thermal properties for specific applications, such as combining lower-aspect-ratio particles for improved dispersion stability with higher-aspect-ratio particles for enhanced thermal conductivity.

Commercial hBN nanoparticle grades suitable for the dielectric nanofluid may be obtained from various suppliers that provide materials characterized for thermal management applications. By way of non-limiting example, suitable hBN grades may include those available from 3M Company, such as 3M Boron Nitride Cooling Filler Agglomerates, which can provide hBN in forms suitable for dispersion in silicone fluids including the base fluid 105 disclosed herein. In some preferred embodiments, hBN grades from Momentive Performance Materials, such as the PolarTherm family of products including PolarTherm PT120, may be employed due to their characterized thermal properties and availability in various particle size distributions ranging from about 50 nm to about 500 nm. Alternatively, hBN grades from Saint-Gobain, such as the Combat family of boron nitride products, may be selected based on their purity levels exceeding about 98% and particle morphology characteristics suitable for nanofluid formulations. In some instances, hBN grades from Denka Company may be utilized, as this supplier provides hBN materials in forms that can be compatible with silicone-based fluid systems and that exhibit platelet morphologies with aspect ratios within the ranges disclosed herein. The selection of a specific commercial hBN grade may depend on factors including the desired particle size distribution, the purity level, the surface chemistry of the particles, and the compatibility with the base fluid 105 and other nanofluid components such as the dispersant, anti-foam agent, and thermal stabilizer.

In another preferred embodiment, hBN grades from multiple suppliers may be evaluated during formulation development to identify the grade that provides optimal performance characteristics for the intended cooling application, including thermal conductivity enhancement, dispersion stability, and rheological behavior. The surface chemistry of commercial hBN grades can vary depending on the manufacturing process and post-treatment steps employed by the supplier, which may influence the compatibility of the nanoparticles 110 with the dispersant and the base fluid 105. In some instances, hBN grades that have undergone surface oxidation treatments may exhibit improved wettability in silicone fluids, potentially facilitating initial dispersion during the mixing process as illustrated in FIG. 3 at step 310. Optionally, the hBN nanoparticles may be subjected to surface functionalization with silane coupling agents as disclosed herein to further enhance compatibility with the base fluid 105 and improve long-term dispersion stability over storage periods of from about 6 months to about 5 years. As illustrated in FIG. 4, the pre-dispersion preparation stage of the manufacturing process may be configured to accommodate different commercial hBN grades by adjusting the high-shear mixing parameters based on the specific particle characteristics of the selected grade. The flexibility in hBN grade selection can allow the dielectric nanofluid formulation to be tailored for different application requirements while maintaining the thermal conductivity, dielectric strength, and dispersion stability characteristics disclosed herein.

The present disclosure provides for the incorporation of a dispersant into the dielectric nanofluid formulation to facilitate stable dispersion of nanoparticles 110 within the base fluid 105 over extended periods of storage and operation. In a preferred embodiment, the dispersant may be configured to adsorb onto the surface of the nanoparticles 110 dispersed within the base fluid 105, creating a physical barrier that can maintain separation between individual particles in the fluid. As illustrated in FIG. 1, the dispersant molecules can extend outward from the surface of the hBN nanoparticles into the surrounding base fluid 105, where the anti-foam agent components represented as solid circles and the thermal stabilizers represented as star shapes are also distributed throughout the formulation. The dispersant may provide steric stabilization by extending polymer chains from the adsorbed dispersant molecules into the surrounding base fluid 105 medium, which can effectively increase the interparticle distance and inhibit agglomeration of the nanoparticles 110 during circulation through cooling systems. In some instances, the resulting steric hindrance may prevent the nanoparticles 110 from coming into close contact with each other, thereby reducing the formation of larger aggregates that could otherwise compromise the nanofluid's thermal performance and flow characteristics through cold plates 206 and microchannels. The stabilization mechanism provided by the dispersant can contribute to maintaining uniform nanoparticle distribution throughout the cooling system 215 during circulation, which may help prevent clogging in microchannels having characteristic dimensions in the range of from about 0.1 mm to about 10 mm and in cold plates 206 as illustrated in FIG. 2.

In some preferred embodiments, the dielectric nanofluid comprises a dispersant that may be configured to be compatible with both the fluid and the nanoparticles 110 suspended therein. The dispersant can provide steric stabilization of the nanoparticles 110 by adsorbing onto the nanoparticle surface and extending polymer chains into the surrounding base fluid 105, thereby maintaining interparticle spacing and inhibiting agglomeration over time during storage periods of from about 6 months to about 5 years and during operational lifetimes of from about 1 year to about 10 years. In a preferred embodiment, the base fluid 105 comprises PDMS and the nanoparticles 110 comprise hBN, and the dispersant may be selected based on its ability to interact favorably with both the silicone-based PDMS matrix and the surface chemistry of the hBN nanoparticles. The molecular architecture of the dispersant can influence the thickness of the steric barrier formed around each nanoparticle, which may affect the long-term stability of the suspension during circulation through cooling systems as illustrated in FIG. 2. Optionally, the dispersant may undergo optimization of its molecular weight and functional group distribution to maximize its interaction with both the nanoparticles 110 and the base fluid 105 for specific application requirements. In another preferred embodiment, the dispersant can be introduced during the pre-dispersion stage of nanofluid preparation as illustrated in FIG. 4 to facilitate initial wetting and distribution of the hBN nanoparticles within the base fluid 105.

Various dispersant types that may be suitable for incorporation into the dielectric nanofluid formulation depending on the specific application requirements and operating conditions. Suitable dispersants for use in the present disclosure may include, but are not limited to, siloxane-based copolymers such as polyether-modified siloxanes, silane-terminated polyethers, silicone-grafted polyacrylates, and combinations thereof. In a preferred embodiment, polyether-modified siloxanes can effectively interact with both the silicone-based base fluid 105 and the hBN nanoparticles due to their amphiphilic molecular structure, which may enable favorable interactions at the interface between the hydrophobic PDMS medium and the surface of the hBN nanoparticles. Alternatively, functionalized polymers with silicone-compatible groups, such as silane-terminated polyethers or silicone-grafted polyacrylates, may be employed as specialized dispersants designed to provide long-term stability in silicone-based systems while offering compatibility with inorganic nanoparticles like hBN. A non-limiting commercial example of a suitable dispersant is a siloxane-compatible copolymer functionally equivalent to the product sold under the designation Dow Corning Q2-5211, which may provide favorable dispersion characteristics in PDMS-based formulations for electronic cooling applications. In some instances, a combination of dispersants may be employed to achieve synergistic effects and further improve the overall stability of the nanofluid system, where the selection of a specific dispersant or combination of dispersants can depend on factors including the particle size distribution of the hBN nanoparticles in the range of from about 50 nm to about 500 nm, the viscosity grade of the base fluid 105 in the range of from about 50 cSt to about 1000 cSt, and the intended operating conditions of the cooling system 215.

In some preferred embodiments, the dispersant may be present at a concentration of from about 0.1% w/w to about 10% w/w of the dielectric nanofluid, which can encompass a broad range suitable for different formulation requirements and application conditions in electronic cooling systems. In a preferred embodiment, the dispersant may be present at a concentration of from about 0.5% w/w to about 5% w/w of the dielectric nanofluid, which can provide effective stabilization of the hBN nanoparticles while minimizing potential impacts on the thermal and electrical properties of the nanofluid formulation. In another preferred embodiment, the dispersant may be present at a concentration of from about 1% w/w to about 2% w/w of the dielectric nanofluid, which can represent an optimized loading level for data center cooling applications where both dispersion stability and thermal performance are considerations. The concentration of the dispersant in the formulation may be configured to provide sufficient stabilization without adversely affecting the thermal conductivity of at least about 1.0 W/m·K or the dielectric strength of at least about 15 kV/mm of the nanofluid. In some instances, lower dispersant concentrations within these ranges may be selected for applications where maximizing thermal conductivity is prioritized, while higher concentrations may be employed in applications where extended shelf life of from about 6 months to about 5 years or enhanced resistance to settling is desired. Alternatively, the dispersant concentration can be adjusted based on the specific hBN nanoparticle loading in the range of from about 20% w/w to about 55% w/w, particle size distribution, and the viscosity characteristics of the base fluid 105 to achieve optimal dispersion stability for the intended cooling application.

In a preferred embodiment, the dispersant may comprise siloxane-based copolymers such as polyether-modified siloxanes, which can effectively interact with both the silicone-based base fluid 105 and the hBN nanoparticles suspended therein to provide steric stabilization. The amphiphilic molecular structure of polyether-modified siloxanes may enable favorable interactions at the interface between the hydrophobic PDMS medium and the surface of the hBN nanoparticles, where the polyether segments can associate with the nanoparticle surface while the siloxane segments extend into the base fluid 105. In some preferred embodiments, functionalized polymers with silicone-compatible groups, such as silane-terminated polyethers or silicone-grafted polyacrylates, may be employed as specialized dispersants configured to provide long-term stability in silicone-based systems while offering compatibility with inorganic nanoparticles like hBN having platelet morphologies with aspect ratios in the range of from about 5 to about 50. The molecular architecture of these dispersants can influence the thickness and density of the steric barrier formed around each nanoparticle, which may affect the resistance to agglomeration over extended periods of operation in cooling systems as illustrated in FIG. 2. In some instances, the effectiveness of the dispersant may be enhanced by optimizing its molecular weight within a range of from about 1,000 g/mol to about 50,000 g/mol, and by tailoring the functional group distribution to maximize interaction with both the nanoparticles 110 and the base fluid 105. Alternatively, the dispersant may be configured to have a molecular weight in the range of from about 5,000 g/mol to about 20,000 g/mol, which can provide a balance between steric stabilization effectiveness and compatibility with the base fluid 105 viscosity characteristics in the range of from about 50 cSt to about 1000 cSt at 25 °C.

In another preferred embodiment, a combination of dispersants may be employed in the dielectric nanofluid formulation to achieve synergistic effects and further improve the overall stability of the nanofluid system during storage and operation. By way of non-limiting example, a primary dispersant comprising a polyether-modified siloxane may be combined with a secondary dispersant comprising a silicone-grafted polyacrylate to provide complementary stabilization mechanisms that can enhance the long-term dispersion stability of the hBN nanoparticles within the base fluid 105. The concentration of the dispersant in the formulation may be configured to provide sufficient stabilization without adversely affecting the thermal or electrical properties of the nanofluid, including maintaining a thermal conductivity of at least about 1.0 W/m·K and a dielectric strength of at least about 15 kV/mm when measured in accordance with ASTM D149. In some instances, the dispersant concentration may be adjusted based on the specific hBN nanoparticle loading in the range of from about 25% w/w to about 55% w/w, particle size distribution in the range of from about 50 nm to about 500 nm, and the viscosity characteristics of the base fluid 105 to achieve optimal dispersion stability for the intended cooling application. As illustrated in FIG. 1, the dispersant molecules can adsorb onto the surface of the hBN nanoparticles and extend polymer chains into the surrounding PDMS medium, creating a physical barrier that maintains separation between individual particles in the fluid during circulation through cold plates 206 and heat exchangers 210 as shown in FIG. 2. The selection of a specific dispersant or combination of dispersants can depend on factors including the particle size distribution of the hBN nanoparticles, the viscosity grade of the base fluid 105, the intended operating temperature range of from about −40 °C to about 200 °C, and the anticipated duration of operation in the cooling system 215.

The dielectric nanofluid may further comprise one or more additives selected to enhance performance and long-term stability during operation in electronic cooling applications. In some preferred embodiments, the one or more additives may be selected from the group consisting of anti-foam agents, thermal stabilizers, corrosion inhibitors, biocides, and combinations thereof. The selection of specific additives can depend on factors including the intended operating environment, the materials of construction in the cooling system 215, the anticipated storage duration, and the thermal load characteristics of the electronic components being cooled. In some instances, a combination of two or more additive types may be configured to provide synergistic effects that enhance the overall performance and reliability of the nanofluid formulation beyond what individual additives might achieve separately. As illustrated in FIG. 1, the additives may be distributed throughout the base fluid 105 along with the hBN nanoparticles, where the anti-foam agent components represented as solid circles and the thermal stabilizers represented as star shapes are shown in the schematic diagram of the nanofluid composition. Alternatively, the additive package may be tailored for specific application requirements, such as data center cooling systems where extended operational lifetimes of from about 1 year to about 10 years are anticipated, or aerospace applications where exposure to extreme temperature variations of from about −55 °C to about 125 °C may occur.

In a preferred embodiment, an anti-foam agent may be present in the dielectric nanofluid formulation to suppress bubble formation during circulation through cooling systems in electronic applications. The anti-foam agent may be configured to reduce surface tension at liquid-air interfaces that can form during pump operation, fluid filling procedures, or when the nanofluid passes through regions of turbulent flow within cold plates 206 or heat exchangers 210 as illustrated in FIG. 2. Suitable anti-foam agents may include, but are not limited to, PDMS derivatives, fluorosilicone compounds, polyether-modified siloxanes, silicone-based defoamers having a molecular weight of at least about 10,000 g/mol, organic defoamers such as polyglycols or fatty alcohol ethoxylates, and combinations thereof. In some instances, the selection of a particular anti-foam agent or combination of anti-foam agents can depend on factors including the anticipated operating temperature range of from about −40 °C to about 200 °C, the flow characteristics of the cooling system 215 including flow rates of from about 0.5 liters per minute to about 50 liters per minute per cold plate, and the potential for air entrainment during system operation. In some preferred embodiments, the anti-foam agent may be present at a concentration of from about 1 ppm to about 1000 ppm of the dielectric nanofluid, which can encompass a broad range suitable for different formulation requirements and operating conditions in data center and high-performance computing environments. In another preferred embodiment, the anti-foam agent may be present at a concentration of from about 10 ppm to about 500 ppm, which can provide effective foam suppression while minimizing potential impacts on other nanofluid properties including thermal conductivity and dielectric strength. Alternatively, the anti-foam agent may be present at a concentration of from about 50 ppm to about 200 ppm, which can represent an optimized loading level for data center cooling applications where both foam control and thermal performance are considerations during sustained operation over periods of from about 1 year to about 10 years.

In some preferred embodiments, the dielectric nanofluid may further comprise a corrosion inhibitor that may be configured to provide protection for system components that contact the nanofluid during circulation through the cooling circuit. As illustrated in FIG. 2, the dielectric nanofluid circulates through the cooling system 215 and contacts various components including cold plates 206 constructed from materials such as copper or aluminum alloys, pumps 220 with metallic impellers and housings, heat exchangers 210 with metallic tubes and fins, and polymeric tubing and seals, where corrosion protection may be beneficial for maintaining system integrity over extended periods of operation. Suitable corrosion inhibitors may include, but are not limited to, sodium molybdate, benzotriazole, tolyltriazole, sodium nitrite, phosphate-based inhibitors, organic acid salts, proprietary blends of organic and inorganic inhibitors, and combinations thereof. In a preferred embodiment, the corrosion inhibitor may be present at a concentration of from about 10 ppm to about 5000 ppm, which can encompass a broad range suitable for different cooling system 215 materials and operating conditions including temperatures of from about 20 °C to about 65 °C during steady-state operation. In another preferred embodiment, the corrosion inhibitor may be present at a concentration of from about 100 ppm to about 2000 ppm, which can provide effective corrosion protection while minimizing potential impacts on the thermal conductivity of at least about 1.0 W/m·K and the electrical properties including dielectric strength of at least about 15 kV/mm of the nanofluid. Alternatively, the corrosion inhibitor may be present at a concentration of from about 250 ppm to about 1000 ppm, which can represent an optimized loading level for data center cooling applications where compatibility with various metallic and polymeric system components is a consideration over operational lifetimes of from about 5 years to about 15 years. In some instances, the corrosion inhibitor package may be tailored based on the specific metallurgy and material composition of the cooling system 215 components to prevent degradation and maintain system reliability throughout the anticipated service life.

In some preferred embodiments, the dielectric nanofluid may further comprise a biocide that may be configured to inhibit microbial growth during storage periods of from about 6 months to about 5 years and during operation in cooling systems. Microbial contamination can potentially occur during fluid handling, system maintenance, or exposure to environmental contaminants, and the presence of a biocide may help maintain the performance characteristics and stability of the nanofluid formulation over extended periods. Suitable biocides may include, but are not limited to, 1,2-Benzisothiazol-3(2H)-one (BIT), isothiazolinones such as methylisothiazolinone and chloromethylisothiazolinone, 2-bromo-2-nitropropane-1,3-diol, glutaraldehyde, quaternary ammonium compounds, and combinations thereof. In a preferred embodiment, the biocide may be present at a concentration of from about 10 ppm to about 1000 ppm, which can provide a range of antimicrobial protection options depending on the specific storage conditions, anticipated operating environment, and regulatory requirements for the intended application. In another preferred embodiment, the biocide may be present at a concentration of from about 50 ppm to about 500 ppm, which can offer effective microbial inhibition while maintaining compatibility with the base fluid 105, hBN nanoparticles, dispersant, and other nanofluid components. Optionally, the biocide concentration may be adjusted based on factors including the intended storage duration, the operating temperature range of from about −40 °C to about 200 °C, the humidity conditions of the storage environment, and the potential for exposure to environmental contaminants during system maintenance procedures. In some instances, the selection of a specific biocide or combination of biocides can depend on regulatory requirements such as EPA registration for industrial biocides, compatibility considerations with the PDMS base fluid 105 and hBN nanoparticles, and the intended application environment including data centers, aerospace systems, or medical imaging equipment.

In a preferred embodiment, the dielectric nanofluid composition incorporates an anti-foam agent that may be configured to address potential foam formation during operation in electronic cooling applications where the nanofluid circulates through pumps 220, cold plates 206, and heat exchangers 210 at flow rates of from about 0.5 liters per minute to about 50 liters per minute per cold plate. As illustrated in FIG. 1, the anti-foam agent can be distributed throughout the base fluid 105 along with the hBN nanoparticles, dispersant, and thermal stabilizer components to provide foam suppression throughout the nanofluid volume during circulation. The anti-foam agent may function by altering the surface properties of the nanofluid, specifically by reducing surface tension at liquid-air interfaces that can form during circulation through cooling systems, where surface tension reduction can promote the rapid collapse of bubbles as they form. In some instances, foam formation in cooling systems can occur during pump operation at rotational speeds of from about 1000 rpm to about 5000 rpm, fluid filling procedures where air may become entrained in the nanofluid, or when the nanofluid passes through regions of turbulent flow within cold plates 206 having micro-channel structures with characteristic dimensions of from about 50 μm to about 500 μm or heat exchangers 210 with complex flow geometries. By destabilizing bubbles before they can accumulate and coalesce into foam, the anti-foam agent may help ensure that the nanofluid maintains its thermal transport capabilities with thermal conductivity of at least about 1.0 W/m·K across a range of operating conditions encountered in data center cooling applications. Optionally, the anti-foam agent may be selected based on its ability to maintain effectiveness over extended periods of operation without degradation, separation from the nanofluid formulation, or adverse interactions with the hBN nanoparticles and dispersant that could compromise dispersion stability during operational lifetimes of from about 1 year to about 10 years.

In some preferred embodiments, the anti-foam agent may comprise one or more compounds selected from PDMS derivatives, fluorosilicone compounds, polyether-modified siloxanes, silicone-based defoamers having a molecular weight of at least about 10,000 g/mol, and combinations thereof. PDMS derivatives can offer compatibility with the base fluid 105 while providing effective foam control, and in some instances may include dimethyl siloxane polymers with added silica particles at concentrations of from about 1% to about 15% by weight for enhanced defoaming performance in silicone-based nanofluid formulations. In a preferred embodiment, the PDMS derivative anti-foam agents may be configured to have molecular weights in the range of from about 10,000 g/mol to about 100,000 g/mol, which can provide favorable foam suppression characteristics while maintaining compatibility with the base fluid 105 viscosity grades disclosed herein. Fluorosilicone compounds may alternatively be employed as anti-foam agents, as these materials can offer foam control in silicone-based fluid systems while exhibiting enhanced thermal stability at elevated temperatures in the range of from about 100 °C to about 200 °C that may be encountered during cooling system 215 operation. Polyether-modified siloxanes represent another class of anti-foam agents that may be configured to provide effective foam suppression while maintaining compatibility with the hBN nanoparticles, dispersant, and other nanofluid components distributed throughout the formulation as illustrated in FIG. 1. In some instances, the polyether-modified siloxane anti-foam agents may comprise polyethylene oxide or polypropylene oxide segments grafted onto a siloxane backbone, where the polyether segment molecular weight can range from about 200 g/mol to about 5,000 g/mol depending on the desired hydrophilic-lipophilic balance for the specific application.

In another preferred embodiment, organic defoamers such as polyglycols or fatty alcohol ethoxylates may be considered depending on their compatibility with the base fluid 105 and the specific operating conditions of the cooling system 215. Polyglycol-based anti-foam agents may be configured to have molecular weights in the range of from about 400 g/mol to about 4,000 g/mol, which can provide effective foam suppression while maintaining solubility or dispersibility within the PDMS base fluid matrix. Fatty alcohol ethoxylates suitable for use as anti-foam agents may comprise alkyl chains having carbon numbers in the range of from about 8 to about 22, with ethoxylation degrees of from about 2 to about 20 moles of ethylene oxide per mole of fatty alcohol. In some instances, the selection of a particular anti-foam agent or combination of anti-foam agents can depend on factors including the anticipated operating temperature range of from about −40 °C to about 200 °C, the flow characteristics of the cooling system 215 including flow rates of from about 0.5 liters per minute to about 50 liters per minute per cold plate, and the potential for air entrainment during system operation such as during pump startup, fluid filling procedures, or passage through turbulent flow regions within cold plates 206 and heat exchangers 210 as illustrated in FIG. 2. Optionally, the anti-foam agent may be selected based on its ability to maintain effectiveness over extended periods of operation without degradation, phase separation from the nanofluid formulation, or adverse interactions with the hBN nanoparticles and dispersant that could compromise dispersion stability during operational lifetimes of from about 1 year to about 10 years. Alternatively, combinations of two or more anti-foam agent types may be employed to achieve synergistic foam suppression effects across a broader range of operating conditions, such as combining a PDMS derivative for baseline foam control with a fluorosilicone compound for enhanced performance at elevated temperatures exceeding about 150 °C.

The present disclosure provides for the incorporation of a thermal stabilizer into the dielectric nanofluid formulation to preserve the thermal and physical properties of the base fluid 105 and other components across the operational temperature range of the cooling system 215. In a preferred embodiment, the thermal stabilizer may be configured to inhibit degradation mechanisms that could otherwise compromise the performance characteristics of the nanofluid during sustained operation at elevated temperatures encountered in electronic cooling applications. The base fluid 105, which in preferred embodiments comprises polydimethylsiloxane (PDMS), can be susceptible to oxidative degradation when exposed to elevated temperatures in the presence of oxygen, and the thermal stabilizer may function to interrupt or retard these degradation pathways. In some instances, the nanoparticles 110 dispersed within the base fluid 105, which in preferred embodiments comprise hexagonal boron nitride (hBN), may also benefit from the presence of thermal stabilizers that help maintain the integrity of the particle-fluid interface during thermal cycling. As illustrated in FIG. 2, the dielectric nanofluid circulates through the cooling system 215 and may experience temperature variations as it absorbs heat from electronic components at the cold plates 206 and releases heat at the heat exchangers 210, where temperatures may range from approximately 20 °C at the coolant distribution unit return to approximately 50 °C at the cold plate outlet during steady-state operation. The incorporation of thermal stabilizers can contribute to maintaining consistent thermal conductivity, viscosity, and dielectric properties of the nanofluid throughout these temperature excursions and over extended operational lifetimes of from about 1 year to about 10 years in data center cooling applications.

In some preferred embodiments, suitable thermal stabilizers for incorporation into the dielectric nanofluid formulation may include, but are not limited to, hindered phenols, phosphites, thioethers, organophosphorus compounds, sterically hindered amines (HALS), metal deactivators, and combinations thereof. Hindered phenols, such as butylated hydroxytoluene (BHT), pentaerythritol tetrakis(3-(3,5-di-tert-butyl-4-hydroxyphenyl)propionate), and octadecyl 3-(3,5-di-tert-butyl-4-hydroxyphenyl)propionate, may function as primary antioxidants by scavenging free radicals that can initiate oxidative degradation of the PDMS base fluid 105 at elevated temperatures. Phosphite-based thermal stabilizers, such as tris(2,4-di-tert-butylphenyl)phosphite and bis(2,4-di-tert-butylphenyl)pentaerythritol diphosphite, may function as secondary antioxidants by decomposing hydroperoxides that form during the initial stages of oxidative degradation. In another preferred embodiment, thioether-based thermal stabilizers, such as dilauryl thiodipropionate and distearyl thiodipropionate, may be employed to provide hydroperoxide decomposition activity that complements the radical scavenging function of hindered phenol antioxidants. Sterically hindered amines (HALS), such as bis(2,2,6,6-tetramethyl-4-piperidyl)sebacate and poly[[6-[(1,1,3,3-tetramethylbutyl)amino]-1,3,5-triazine-2,4-diyl] [(2,2,6,6-tetramethyl-4-piperidinyl)imino]-1,6-hexanediyl[(2,2,6,6-tetramethyl-4-piperidinyl)imino]]), may provide long-term thermal stabilization through a regenerative mechanism that allows the stabilizer molecules to participate in multiple stabilization cycles. Metal deactivators, such as N, N′-bis(3-(3,5-di-tert-butyl-4-hydroxyphenyl)propionyl)hydrazine, may be incorporated to chelate trace metal ions that could otherwise catalyze oxidative degradation of the base fluid 105 or promote agglomeration of the hBN nanoparticles during extended operation.

In a preferred embodiment, the thermal stabilizer may be configured to function by inhibiting oxidation processes that could otherwise degrade the nanofluid's performance over time during operation at elevated temperatures in the range of from about 50 °C to about 200 °C. The thermal stabilizers may also help maintain the dispersion stability of the hexagonal boron nitride nanoparticles within the base fluid 105 by reducing agglomeration or settling that could occur under thermal stress conditions, where elevated temperatures can increase the kinetic energy of the suspended particles and potentially overcome the steric stabilization provided by the dispersant. In some instances, oxidative degradation of the PDMS base fluid 105 can result in the formation of low-molecular-weight siloxane fragments, crosslinked gel particles, or volatile decomposition products that may alter the viscosity, thermal conductivity, or dielectric properties of the nanofluid formulation. The presence of thermal stabilizers can allow the nanofluid to maintain its heat transfer properties even after prolonged exposure to high temperatures or thermal cycling that may occur during normal cooling system 215 operation, where the nanofluid may experience thousands of temperature cycles over the operational lifetime of the system. As illustrated in FIG. 1, the thermal stabilizer components represented as star shapes are distributed throughout the base fluid 105 along with the hBN nanoparticles, dispersant, and anti-foam agent, where this uniform distribution can provide thermal protection throughout the nanofluid volume during circulation through the cooling system 215. In another preferred embodiment, combinations of thermal stabilizers may be employed to provide synergistic effects, such as combining a primary antioxidant comprising a hindered phenol at a concentration of from about 0.05% w/w to about 1% w/w with a secondary stabilizer comprising a phosphite at a concentration of from about 0.02% w/w to about 0.5% w/w to achieve enhanced thermal protection across a wider range of operating conditions than either stabilizer type could provide individually.

In some preferred embodiments, the thermal stabilizer may be present at a concentration of from about 0.01% w/w to about 5% w/w of the dielectric nanofluid, which can provide a broad range of thermal protection options depending on the specific application requirements and anticipated operating temperatures in electronic cooling systems. In a preferred embodiment, the thermal stabilizer may be present at a concentration of from about 0.05% w/w to about 2% w/w, which can offer effective thermal protection while maintaining the desired rheological properties including kinematic viscosity in the range of from about 50 cSt to about 1000 cSt and electrical properties including dielectric strength of at least about 15 kV/mm of the nanofluid formulation. Alternatively, the thermal stabilizer may be present at a concentration of from about 0.1% w/w to about 1% w/w, which can represent an optimized loading level for applications where sustained operation at elevated temperatures in the range of from about 100 °C to about 175 °C is anticipated in data center cooling systems. The concentration of thermal stabilizer may be adjusted based on factors including the intended operating temperature range, the anticipated duration of high-temperature exposure, the specific PDMS grade employed in the base fluid 105, and the concentration of hBN nanoparticles in the formulation. In some instances, higher concentrations of thermal stabilizers within these ranges may be selected for applications where the nanofluid is expected to operate at temperatures approaching or exceeding about 150 °C for extended periods, such as in high-performance computing environments with concentrated thermal loads exceeding 500 W per processor. Optionally, the thermal stabilizer concentration can be tailored based on accelerated aging tests that simulate the thermal conditions expected during the operational lifetime of the cooling system 215, where test protocols may include exposure to temperatures of from about 100 °C to about 200 °C for durations of from about 100 hours to about 1000 hours to predict long-term stability performance.

The combination of these carefully selected components results in a nanofluid with favorable electrical insulation properties that may be configured to enable direct contact with electronic components in cooling applications. In a preferred embodiment, the high-performance dielectric nanofluid exhibits a dielectric strength of at least about 15 kV/mm when measured in accordance with ASTM D149, which can provide a margin of safety for direct-to-chip cooling applications where the fluid contacts live electronic components. In some preferred embodiments, the dielectric strength may be in the range of from about 15 kV/mm to about 30 kV/mm, which can accommodate various voltage levels encountered in data center and high-performance computing environments. The dielectric strength of the nanofluid may be influenced by factors including the purity of the base fluid 105, the concentration and dispersion quality of the hBN nanoparticles, and the presence of any contaminants or moisture in the formulation. In some instances, the dielectric strength can be enhanced by employing filtration processes during manufacturing to remove particulates that could otherwise create localized field concentrations. As illustrated in FIG. 1, the uniform distribution of hBN nanoparticles within the base fluid 105, facilitated by the dispersant, may contribute to maintaining consistent dielectric properties throughout the nanofluid volume. In another preferred embodiment, the dielectric nanofluid exhibits an electrical conductivity of less than about 1×10⁻⁹ S/m when measured in accordance with ASTM D1169, which can provide effective electrical isolation between the cooling fluid and the electronic components it contacts. In some preferred embodiments, the electrical conductivity may be in the range of from about 1×10⁻¹⁴ S/m to about 1×10⁻⁹ S/m, which can encompass a range of formulations suitable for different electronic cooling applications. The low electrical conductivity of the nanofluid may be attributed to the inherent dielectric properties of the base fluid 105 and the electrically insulating nature of the hBN nanoparticles. In some instances, the electrical conductivity can be maintained at low levels by selecting high-purity PDMS grades and by controlling the ionic content of the additives incorporated into the formulation. Alternatively, the electrical conductivity may be further reduced by employing deionization or purification steps during the manufacturing process to remove trace ionic species. The combination of high dielectric strength and low electrical conductivity may enable the nanofluid to provide efficient thermal management while maintaining electrical isolation in sensitive electronic systems, such as those found in data centers, high-performance computing environments, and other power-dense electronic applications where direct-to-chip cooling can be beneficial.

The present disclosure provides for a dielectric nanofluid that may be configured to exhibit specific heat capacity characteristics suitable for thermal management applications in electronic cooling systems. In a preferred embodiment, the dielectric nanofluid may exhibit a specific heat capacity, measured in accordance with ASTM E1269, in the range of from about 1.0 kJ/kg·K to about 2.0 kJ/kg·K, which can provide favorable heat absorption characteristics for electronic cooling applications where thermal energy storage within the circulating fluid is a consideration. In some preferred embodiments, the specific heat capacity may be in the range of from about 1.2 kJ/kg·K to about 1.8 kJ/kg·K, which can represent a range suitable for data center and high-performance computing environments where heat absorption capacity influences the temperature differential between cold plate inlet and outlet during operation. The specific heat capacity of the dielectric nanofluid formulation may be estimated using a mass-weighted-average approach based on the specific heat capacities of the individual components that comprise the nanofluid. Polydimethylsiloxane (PDMS) base fluids have a specific heat capacity at 25 °C of approximately 1.5 kJ/kg·K, as reported in technical data sheets for commercial PDMS grades, including by way of non-limiting example Dow Xiameter PMX-200 silicone fluid technical data and Gelest DMS silicone fluids product literature. Hexagonal boron nitride (hBN) has a specific heat capacity at 25 °C of approximately 0.8 kJ/kg·K, as reported in standard materials references and technical literature for ceramic thermal management materials.

In another preferred embodiment, for the dielectric nanofluid comprising a base fluid 105 and approximately 40% w/w hBN nanoparticles, a mass-weighted-average specific heat capacity accordingly falls at or near the middle of the foregoing range, which can provide a balance between heat absorption capacity and thermal conductivity enhancement for electronic cooling applications. By way of non-limiting example, a formulation comprising approximately 60% w/w PDMS base fluid having a specific heat capacity of approximately 1.5 kJ/kg·K and approximately 40% w/w hBN nanoparticles having a specific heat capacity of approximately 0.8 kJ/kg·K may yield a mass-weighted-average specific heat capacity of approximately 1.2 kJ/kg·K to approximately 1.3 kJ/kg·K. In some instances, the observed specific heat capacity may vary with the specific viscosity grade or blend of PDMS selected for the base fluid formulation, where different molecular weight distributions can influence the thermophysical properties of the polymer. The specific heat capacity can also be influenced by the identity and concentration of the dispersant, anti-foam agent, thermal stabilizer, and other additives incorporated into the nanofluid, though these components are typically present at concentrations that may have a relatively minor effect on the overall specific heat capacity of the formulation. The temperature of measurement and the measurement technique employed may also affect the observed specific heat capacity values, and in some preferred embodiments, measurements may be conducted at multiple temperatures across the anticipated operating range to characterize the temperature dependence of this property. As illustrated in FIG. 2, the dielectric nanofluid circulates through the cooling system 215 and absorbs heat from electronic components, where the specific heat capacity of the nanofluid can influence the temperature differential between the cold plate inlet at approximately 35 °C and outlet at approximately 50 °C during steady-state operation.

In some preferred embodiments, the specific heat capacity may be tailored by adjusting the hBN nanoparticle concentration within the ranges disclosed herein, where lower nanoparticle loadings may result in specific heat capacities closer to that of the neat base fluid 105, and higher nanoparticle loadings may result in specific heat capacities that trend toward the lower end of the disclosed range. By way of non-limiting example, a formulation comprising approximately 25% w/w hBN nanoparticles may exhibit a specific heat capacity of approximately 1.3 kJ/kg·K to approximately 1.4 kJ/kg·K, while a formulation comprising approximately 55% w/w hBN nanoparticles may exhibit a specific heat capacity of approximately 1.1 kJ/kg·K to approximately 1.2 kJ/kg·K. The selection of nanoparticle concentration may involve balancing the thermal conductivity enhancement provided by higher nanoparticle loadings against the heat absorption capacity associated with higher specific heat capacity values. In some instances, applications with high flow rates through the cooling circuit may benefit from formulations with higher nanoparticle concentrations that prioritize thermal conductivity, while applications with lower flow rates may benefit from formulations with lower nanoparticle concentrations that provide greater heat absorption capacity per unit mass of circulating fluid. Optionally, the specific heat capacity of the dielectric nanofluid may be characterized using differential scanning calorimetry (DSC) techniques in accordance with ASTM E1269 to verify that the formulation meets specifications for the intended cooling application. Alternatively, the specific heat capacity may be measured using modulated DSC techniques or other calorimetric methods that can provide additional information regarding the temperature dependence of this property across the anticipated operating temperature range.

The present disclosure provides for a dielectric nanofluid that may be configured to be operable across a broad temperature range suitable for various electronic cooling applications and environmental conditions. In a preferred embodiment, the dielectric nanofluid may be configured to be operable across a temperature range of from about −40 °C to about 200 °C, which can accommodate data center cooling applications, high-performance computing environments, aerospace systems, and other electronic applications where temperature variations may occur during operation or storage. In some preferred embodiments, the operating temperature range may be from about −50 °C to about 175 °C, which can provide flexibility for installations in cold-climate environments or applications with moderate thermal loads where the upper temperature limit may be constrained by system design considerations. The lower bound of the operating temperature range may be adjusted by selection of the base fluid 105 or by blending PDMS grades of differing molecular weight and viscosity, because the pour point of PDMS scales with molecular weight and affects the low-temperature fluidity of the formulation. By way of non-limiting example, low-viscosity PDMS grades having a kinematic viscosity of approximately 5 cSt to approximately 50 cSt at 25 °C typically have pour points below approximately −55 °C, which can enable operation in cold-start conditions or cold-climate installations where ambient temperatures may fall below −40 °C. Medium-viscosity PDMS grades having a kinematic viscosity of approximately 100 cSt to approximately 500 cSt at 25 °C typically have pour points from approximately −45 °C to approximately −55 °C, which can provide suitable low-temperature performance for data center cooling applications where cold-start conditions may be encountered during system commissioning or after extended shutdown periods.

In another preferred embodiment, blending a lower-viscosity PDMS grade with a higher-viscosity PDMS grade may allow the pour point of the base fluid 105 to be tailored to specific application requirements while maintaining desired rheological properties at operating temperatures within the range of from about 20 °C to about 65 °C for typical data center cooling applications. By way of non-limiting example, a blend comprising approximately 30% by weight of a 20 cSt PDMS grade having a pour point below approximately −60 °C and approximately 70% by weight of a 200 cSt PDMS grade having a pour point of approximately −50 °C may yield a blended base fluid 105 with a pour point below approximately −50 °C while maintaining a target kinematic viscosity suitable for circulation through cold plates 206 and microchannels. The upper bound of the operating temperature range is determined by the thermal decomposition temperature of the base fluid 105 and by the efficacy of the thermal-stabilizer package incorporated into the nanofluid formulation. Under substantially inert conditions, PDMS remains chemically stable at temperatures exceeding approximately 250 °C, which can provide a margin of safety for high-temperature excursions that may occur during transient thermal events or system malfunctions. Under oxygen-containing conditions, useful operating life may be shorter at elevated temperatures and can be extended by appropriate thermal stabilizers and antioxidants selected for compatibility with the base fluid 105, such as hindered phenols at concentrations of from about 0.05% w/w to about 1% w/w or phosphite-based secondary antioxidants at concentrations of from about 0.02% w/w to about 0.5% w/w. In some instances, the thermal stabilizer concentration may be increased for applications where sustained operation at temperatures above approximately 150 °C is anticipated, such as in high-performance computing environments with concentrated thermal loads exceeding 500 W per processor.

In some preferred embodiments, the operating temperature range may be narrowed for specific applications where the nanofluid is expected to operate within a more limited temperature window, allowing for optimization of other formulation parameters such as viscosity or nanoparticle loading to maximize performance within the constrained temperature range. By way of non-limiting example, a data center cooling application operating within a temperature range of from about 20 °C to about 65 °C may employ a formulation optimized for viscosity and thermal conductivity within this range without the need for additives or base fluid 105 modifications that would extend the operating range to extreme temperatures. As illustrated in FIG. 2, the dielectric nanofluid may experience temperature variations as it circulates through the cooling system 215, entering cold plates 206 at approximately 35 °C and exiting at approximately 50 °C, which falls well within the disclosed operating temperature range and represents typical steady-state operating conditions for data center cooling applications. The temperature differential of approximately 15 °C between the cold plate inlet and outlet can demonstrate the heat absorption capacity of the dielectric nanofluid during circulation through the cooling circuit. Optionally, the operating temperature range may be characterized through accelerated aging tests that expose the nanofluid to temperatures at or near the upper bound of the operating range for extended periods to verify that the formulation maintains its thermal conductivity, viscosity, and dielectric properties over the anticipated operational lifetime. Alternatively, low-temperature performance may be verified through pour point measurements, low-temperature viscosity measurements, or cold-start pumpability tests that simulate the conditions encountered during system startup in cold-climate installations or after extended shutdown periods.

The present disclosure provides for a dielectric nanofluid that may be configured to operate within a cooling system 215 designed to provide thermal management for computing systems and electronic components in data center and high-performance computing environments. As illustrated in FIG. 2, the cooling system 215 can comprise a server rack 205 configured to house one or more heat-generating electronic components, one or more cold plates 206 positioned in thermal contact with the heat-generating electronic components, a coolant distribution unit fluidly coupled to the one or more cold plates 206 and configured to circulate a coolant through the one or more cold plates 206, and one or more heat exchangers 210 fluidly coupled to the coolant distribution unit and configured to remove heat from the coolant. In a preferred embodiment, the server rack 205 may be configured to house multiple heat-generating computing devices, such as processors operating at thermal design power levels of from about 100 W to about 700 W, graphics processing units generating heat fluxes of from about 50 W/cm² to about 300 W/cm², memory modules, storage devices, and other electronic components that generate thermal loads during operation. The cold plates 206 can be attached to or positioned adjacent to the heat-generating elements and may be designed to efficiently absorb and transfer thermal energy from the electronic components to the circulating dielectric nanofluid through conductive heat transfer at the solid-liquid interface. In some preferred embodiments, the cold plates 206 may comprise micro-channel structures configured to increase thermal contact area with the dielectric nanofluid, where the micro-channel structures can have characteristic dimensions in the range of from about 50 μm to about 500 μm to provide high surface area to volume ratios for enhanced heat transfer. The coolant distribution unit may serve as a central hub for managing the circulation of the dielectric nanofluid throughout the cooling circuit, and can include one or more pumps 220 configured to deliver the nanofluid at controlled flow rates, flow control valves for directing fluid to specific zones within the system, and monitoring instrumentation for tracking system performance parameters.

In another preferred embodiment, the dielectric nanofluid circulating through the cooling system 215 comprises a base fluid 105 and nanoparticles 110 dispersed therein, where the base fluid 105 may comprise polydimethylsiloxane (PDMS) and the nanoparticles 110 may comprise hexagonal boron nitride (hBN) at a concentration of at least about 20% w/w. The dielectric nanofluid formulation employed in the cooling system 215 may further comprise a dispersant configured to provide steric stabilization of the hBN nanoparticles within the base fluid 105, an anti-foam agent to suppress bubble formation during circulation through pumps 220 and cold plates 206, and a thermal stabilizer to maintain fluid properties across the operational temperature range of from about −40 °C to about 200 °C. In some instances, the dielectric nanofluid may additionally comprise a corrosion inhibitor at concentrations of from about 100 ppm to about 2000 ppm to provide protection for metallic system components such as copper or aluminum cold plates 206, and a biocide at concentrations of from about 50 ppm to about 500 ppm to inhibit microbial growth during extended storage and operation periods. Heat exchangers 210 may be strategically positioned within the system to facilitate the transfer of heat from the dielectric nanofluid to an external environment or secondary cooling medium, which can help provide continuous cooling capacity during sustained operation at thermal loads of from about 1 kW to about 100 kW per server rack 205. The heat exchangers 210 can be configured as liquid-to-liquid heat exchangers 210 employing facility water or chilled water as the secondary medium, liquid-to-air heat exchangers 210 utilizing ambient air for heat rejection, or combinations thereof depending on the specific installation requirements and available facility infrastructure. Optionally, the heat exchangers 210 may be sized to accommodate peak thermal loads that exceed steady-state operating conditions by a factor of from about 1.2 to about 2.0, providing margin for transient workload spikes that may occur during computational bursts or system startup sequences.

As illustrated in FIG. 2, the flow of the dielectric nanofluid may begin at the coolant distribution unit, where the fluid can be pumped at a controlled rate and pressure through the cooling circuit to the one or more cold plates 206 in thermal contact with the heat-generating electronic components. In a preferred embodiment, the coolant distribution unit may be configured to circulate the dielectric nanofluid at flow rates in the range of from about 0.5 liters per minute to about 50 liters per minute per cold plate, depending on the thermal load requirements of the electronic components and the system configuration including tubing diameter, cold plate geometry, and pump capacity. From the coolant distribution unit, the chilled dielectric nanofluid can travel through insulated pipes or tubing constructed from materials such as stainless steel, copper, or polymeric materials including fluoropolymers or silicone rubber to the cold plates 206 attached to the servers within the rack, where the insulation may help minimize thermal losses during transit and maintain the desired inlet temperature. In some preferred embodiments, the dielectric nanofluid may enter the one or more cold plates 206 at a temperature in the range of from about 25 °C to about 40 °C, with a preferred inlet temperature of approximately 35 °C for data center applications where facility chilled water is available as a secondary cooling medium. The dielectric nanofluid can flow through channels, passages, or microstructures within the cold plates 206, coming into close thermal contact with the heat-generating electronic components to facilitate heat absorption through convective heat transfer at the fluid-solid interface. In some instances, the cold plate channels may have characteristic dimensions in the range of from about 0.1 mm to about 10 mm, which can be selected to balance heat transfer performance with pressure drop considerations and to accommodate the viscosity characteristics of the dielectric nanofluid formulation having kinematic viscosity in the range of from about 50 cSt to about 1000 cSt at 25 °C.

In some preferred embodiments, the dielectric nanofluid may absorb heat generated by the processors and other electronic devices as it passes through the cold plates 206, resulting in a temperature increase between the inlet and outlet of the cold plates 206 that demonstrates the heat absorption capacity of the formulation. After passing through the cold plates 206 and absorbing thermal energy from the electronic components, the dielectric nanofluid can exit the one or more cold plates 206 at a temperature in the range of from about 45 °C to about 60 °C during steady-state operation, with a preferred outlet temperature of approximately 50 °C for typical data center operating conditions where processor junction temperatures are maintained below manufacturer-specified limits. This temperature differential between the inlet and outlet of the cold plates 206 may be in the range of from about 10 °C to about 25 °C, which can demonstrate the heat absorption capacity of the dielectric nanofluid during circulation and can be influenced by factors including the thermal conductivity of the nanofluid formulation of at least about 1.0 W/m·K, the specific heat capacity of the nanofluid in the range of from about 1.0 kJ/kg·K to about 2.0 kJ/kg·K, and the flow rate through the cold plates 206. In another preferred embodiment, the temperature differential may be configured to be approximately 15 °C, which can represent a balance between heat removal efficiency and pumping power requirements for data center applications where energy consumption is a consideration. The specific temperature differential achieved during operation can depend on factors including the thermal load of the electronic components being cooled, the flow rate of the dielectric nanofluid through the cold plates 206, the thermal conductivity enhancement provided by the hBN nanoparticles at concentrations of from about 25% w/w to about 55% w/w, and the design of the cold plates 206 including channel geometry and surface enhancement features. Alternatively, the operating temperatures and temperature differentials may be adjusted based on the specific requirements of the electronic components being cooled, such as manufacturer-specified junction temperature limits of from about 85 °C to about 105 °C for server processors, reliability considerations for extended operational lifetimes of from about 5 years to about 15 years, or workload characteristics that result in variable thermal loads during operation.

Upon exiting the one or more cold plates 206, the warmed dielectric nanofluid may be directed to the one or more heat exchangers 210 within the cooling system, where thermal energy can be transferred from the dielectric nanofluid to a secondary cooling medium. As illustrated in FIG. 2, the heat exchangers 210 can facilitate the transfer of thermal energy from the dielectric nanofluid to a secondary cooling medium, which may comprise facility water, chilled water, ambient air, or another liquid coolant depending on the available infrastructure and installation requirements. In a preferred embodiment, the heat exchange process can effectively lower the temperature of the dielectric nanofluid by an amount in the range of from about 10 °C to about 30 °C, preparing it for recirculation through the one or more cold plates 206 in thermal contact with the heat-generating electronic components. In some preferred embodiments, the temperature reduction achieved at the heat exchangers 210 may be in the range of from about 15 °C to about 25 °C, which can represent typical operating conditions for data center cooling applications where facility chilled water at temperatures of from about 7 °C to about 15 °C is available as the secondary cooling medium. After passing through the heat exchangers 210, the cooled dielectric nanofluid may return to the coolant distribution unit at a temperature in the range of from about 20 °C to about 35 °C to begin the circulation cycle anew, with a preferred return temperature of approximately 20 °C when facility chilled water is employed as the secondary cooling medium. In some instances, higher return temperatures in the range of from about 25 °C to about 35 °C may be observed when air-cooled heat exchangers 210 are utilized, where the heat rejection capacity can be influenced by ambient air temperature and heat exchanger sizing. This continuous circulation can help ensure that heat is consistently removed from the electronic components within the server rack, which may contribute to maintaining operational junction temperatures within manufacturer-specified limits for processors and other heat-generating components during sustained workloads.

The present disclosure provides for a cooling system 215 having a closed-loop configuration that can help prevent contamination of the dielectric nanofluid and may contribute to maintaining its performance characteristics over extended periods of operation spanning from about 1 year to about 10 years. In a preferred embodiment, the dielectric nanofluid circulating through the cooling system 215 comprises a base fluid 105 and nanoparticles 110 dispersed therein, where the base fluid 105 may comprise polydimethylsiloxane (PDMS) and the nanoparticles 110 may comprise hexagonal boron nitride (hBN) at a concentration of at least about 20% w/w. The use of the dielectric nanofluid in this cooling system 215 can offer advantages for data center applications, including efficient heat transfer from the electronic components to the coolant due to the enhanced thermal conductivity of at least about 1.0 W/m·K provided by the hBN nanoparticles dispersed within the PDMS base fluid. In some preferred embodiments, this thermal conductivity enhancement may result in lower flow rates or smaller temperature differentials compared to conventional cooling fluids lacking nanoparticle enhancement, which can potentially reduce pumping power requirements by from about 10% to about 40% and decrease overall energy consumption of the cooling system. Additionally, the dielectric properties of the PDMS-based nanofluid, including a dielectric strength of at least about 15 kV/mm when measured in accordance with ASTM D149 and an electrical conductivity of less than about 1×10⁻⁹ S/m when measured in accordance with ASTM D1169, can provide an added layer of safety, as the fluid may come into direct contact with electronic components operating at voltages of from about 1 V to about 48 V without risk of electrical short circuits or component damage. This characteristic may allow for more compact cooling system 215 designs with reduced footprints of from about 10% to about 50% compared to systems employing conductive coolants that require electrical isolation, and can enable higher power densities within the server racks of from about 20 kW to about 100 kW per rack compared to conventional air-cooled configurations. Alternatively, the dielectric properties of the nanofluid may permit direct immersion cooling configurations in some applications, where electronic components are partially or fully submerged in the cooling fluid to maximize thermal contact area and heat transfer efficiency.

In another preferred embodiment, the cooling system design may incorporate features configured to optimize the performance of the dielectric nanofluid during operation in data center and high-performance computing environments. As illustrated in FIG. 2, the one or more cold plates 206 may be engineered with micro-channel structures, pin-fin arrays, or enhanced surface geometries to maximize heat transfer from the electronic components to the circulating dielectric nanofluid through increased thermal contact area. In some instances, the micro-channel structures may have characteristic dimensions in the range of from about 50 μm to about 500 μm, which can provide high surface area to volume ratios for enhanced convective heat transfer at the fluid-solid interface while accommodating the viscosity characteristics of the dielectric nanofluid formulation having kinematic viscosity in the range of from about 50 cSt to about 1000 cSt at 25 °C. The coolant distribution unit may include advanced flow control mechanisms, such as variable-speed pumps 220 capable of delivering flow rates in the range of from about 0.5 liters per minute to about 50 liters per minute per cold plate, or electronically actuated valves, to adjust the dielectric nanofluid circulation rate based on real-time thermal load demands detected by temperature sensors positioned throughout the system. In some preferred embodiments, sensors positioned throughout the cooling system 215 may monitor temperatures at multiple locations including cold plate inlets and outlets, flow rates through individual branches of the cooling circuit, and pressure differentials across filters and heat exchangers 210, allowing for dynamic adjustments to maintain optimal cooling performance during varying workload conditions that may cause thermal loads to fluctuate by factors of from about 1.5 to about 3.0 during computational bursts. Optionally, redundant pumps 220 or heat exchangers 210 may be incorporated into the cooling system 215 to help ensure system reliability and continuous operation in the event of component failure or scheduled maintenance activities, where the redundant components can be sized to accommodate peak thermal loads that exceed steady-state operating conditions by a factor of from about 1.2 to about 2.0.

The present disclosure provides for maintenance and monitoring features that may be incorporated into the dielectric nanofluid cooling system 215 to facilitate long-term operation and performance verification. In a preferred embodiment, the cooling system 215 may include filtration components configured to remove particulates that could potentially accumulate over time during circulation through pumps 220, cold plates 206, and heat exchangers 210, which can help ensure the long-term stability and performance of the dielectric nanofluid during extended operation over periods of from about 1 year to about 10 years. The filtration components may comprise filters with pore sizes in the range of from about 1 μm to about 25 μm, which can capture agglomerates, contaminants, or degradation products while permitting the dispersed hBN nanoparticles having primary particle sizes in the range of from about 50 nm to about 500 nm to pass through without restriction. In some preferred embodiments, periodic sampling and analysis of the dielectric nanofluid may be conducted at intervals of from about 1 month to about 12 months to verify that its thermal conductivity of at least about 1.0 W/m·K and dielectric strength of at least about 15 kV/mm remain within specified ranges over the operational lifetime of the system. The coolant distribution unit may incorporate features for easy draining and refilling of the dielectric nanofluid through valved connections and drain ports, which can facilitate maintenance procedures without extensive system downtime exceeding about 2 hours to about 8 hours depending on the system volume. Optionally, the cooling system 215 may include provisions for online monitoring of dielectric nanofluid properties, such as viscosity sensors capable of detecting changes in fluid rheology, particle counters for assessing dispersion stability, or conductivity sensors for monitoring dielectric properties, to provide real-time assessment of fluid condition and enable predictive maintenance scheduling based on trending analysis of the monitored parameters.

In some preferred embodiments, the cooling system 215 may be configured to operate with nanofluid volumes in the range of from about 1 liter to about 1000 liters depending on the scale of the installation and the number of server racks 205 being cooled. The system pressure during operation may be maintained in the range of from about 0.1 bar to about 10 bar gauge, which can be selected based on the system geometry, elevation changes, and flow rate requirements. Alternatively, the cooling system 215 may be configured to operate at sub-atmospheric pressures in some portions of the circuit, which can help reduce the risk of leakage at fittings and connections. By leveraging the properties of the high-performance dielectric nanofluid as described herein, this cooling system 215 can provide an efficient and reliable solution for managing the thermal challenges in modern data center environments. The combination of enhanced thermal conductivity, dielectric properties, and long-term stability of the nanofluid may enable higher computational densities and improved energy efficiency compared to conventional cooling approaches. In another preferred embodiment, the cooling system 215 may be scaled to accommodate multiple server racks 205 within a data center, with centralized coolant distribution and heat rejection infrastructure serving an array of cold plates 206 distributed throughout the facility.

In addition to its primary application in data center cooling, the high-performance dielectric nanofluid may demonstrate potential for adaptation across various industries with demanding thermal management requirements. In a preferred embodiment, the nanofluid cooling system 215 may be modified to address the unique challenges encountered in the aerospace sector, including aircraft engines and avionics systems. By adjusting the concentration of hBN nanoparticles within a range of from about 25% w/w to about 55% w/w, the thermal conductivity and viscosity of the high-performance dielectric nanofluid may be configured to be optimized for the extreme temperature fluctuations and high-altitude conditions encountered during flight operations. In some preferred embodiments, the incorporation of secondary nanoparticles 110, such as aluminum oxide (Al2O3) at concentrations of from about 1% w/w to about 15% w/w, or silicon carbide (SiC) at concentrations of from about 0.5% w/w to about 10% w/w, may further enhance the nanofluid's performance in aerospace applications where elevated thermal loads are anticipated. Alternatively, combinations of hBN with these secondary nanoparticles 110 may be employed to achieve synergistic thermal enhancement effects tailored to specific aerospace operating conditions. These modifications may result in improved heat dissipation from avionics components, potentially leading to increased reliability and reduced maintenance intervals for aircraft thermal management systems operating at altitudes of from about 10,000 feet to about 50,000 feet.

In another preferred embodiment, the automotive industry may benefit from the advanced cooling capabilities of the high-performance dielectric nanofluid. In some instances, the nanofluid may be adapted to manage thermal loads in electric vehicle (EV) applications, including battery packs operating at temperatures of from about 20 °C to about 45 °C, power electronics generating heat fluxes of from about 50 W/cm² to about 200 W/cm², and electric motors with thermal design power levels of from about 50 kW to about 500 kW. By using a blend of different viscosity PDMS oils, such as combining a first PDMS grade having a kinematic viscosity of from about 10 cSt to about 50 cSt with a second PDMS grade having a kinematic viscosity of from about 200 cSt to about 1000 cSt, the overall viscosity and flow characteristics of the high-performance dielectric nanofluid may be configured to be fine-tuned to optimize cooling efficiency in compact EV powertrains. In some preferred embodiments, motorsport applications where extreme heat generation and high G-forces of from about 2 G to about 6 G are common may leverage the nanofluid's stability and heat transfer properties to maintain optimal operating temperatures for engines and brake systems operating at temperatures of from about 100 °C to about 300 °C. The use of alternative corrosion inhibitors, such as benzotriazole at concentrations of from about 100 ppm to about 2000 ppm, or a proprietary blend of organic and inorganic inhibitors at concentrations of from about 250 ppm to about 5000 ppm, may be implemented to help ensure long-term compatibility with various automotive materials including aluminum alloys, copper components, and polymeric seals. Optionally, the corrosion inhibitor package may be tailored based on the specific metallurgy and material composition of the automotive cooling system components to prevent degradation over operational lifetimes of from about 5 years to about 15 years.

In a preferred embodiment, the high-performance dielectric nanofluid may be applied in the field of robotics and automated manufacturing to cool high-precision industrial robots and automated systems. The nanofluid's high thermal conductivity of at least about 1.0 W/m·K and electrical insulation properties with dielectric strength exceeding about 15 kV/mm may allow for more compact and efficient cooling of robotic actuators generating heat loads of from about 10 W to about 500 W, control systems, and sensors operating at frequencies of from about 1 kHz to about 100 kHz. By modifying the base fluid 105 composition or incorporating specialized additives at concentrations of from about 0.01% w/w to about 5% w/w, the high-performance dielectric nanofluid may be configured to be tailored to withstand the repetitive motions at cycle rates of from about 1 Hz to about 100 Hz and vibrations at frequencies of from about 10 Hz to about 1000 Hz typical in industrial robotics applications. In some preferred embodiments, the hBN nanoparticles may be surface-functionalized to improve their compatibility with the base fluid 105, to enhance long-term dispersion stability over operational periods of from about 1 year to about 10 years, and to suppress agglomeration during extended circulation through robotic cooling circuits. Surface functionalization may be carried out prior to introducing the hBN nanoparticles into the base fluid 105, or alternatively in situ during a pre-dispersion step as illustrated in FIG. 4. In some instances, the surface functionalization may comprise reacting the hBN nanoparticles with a silane coupling agent selected from the group consisting of (3-aminopropyl)triethoxysilane (APTES), octyltriethoxysilane (OTES), (3-glycidyloxypropyl)trimethoxysilane, vinyltrimethoxysilane, a fluorosilane, and combinations thereof.

In some preferred embodiments, the silane coupling agent may be present at a loading of from about 0.1% to about 10% by weight relative to the hBN nanoparticles, which can encompass a broad range suitable for different functionalization requirements and nanoparticle surface characteristics. In a preferred embodiment, the silane coupling agent may be present at a loading of from about 0.5% to about 5% by weight relative to the hBN nanoparticles, which can provide effective surface modification while maintaining the thermal properties of the nanoparticles 110. In another preferred embodiment, the silane coupling agent may be present at a loading of from about 1% to about 3% by weight relative to the hBN nanoparticles, which can represent an optimized loading level for achieving enhanced dispersion stability in PDMS-based nanofluid formulations. In some instances, the hBN nanoparticles may additionally or alternatively be subjected to an oxidative surface treatment to introduce hydroxyl groups that enhance subsequent silane coupling reactions. Suitable oxidative surface treatments may include, but are not limited to, treatment with hydrogen peroxide at concentrations of from about 3% to about 30%, ozone exposure at concentrations of from about 1 ppm to about 100 ppm, or plasma treatment using oxygen, argon, or air plasma at power levels of from about 10 W to about 500 W for durations of from about 1 minute to about 60 minutes. The implementation of the high-performance dielectric nanofluid in robotics cooling may contribute to increased precision, reduced downtime, and extended operational lifespans of from about 20,000 hours to about 100,000 hours for automated manufacturing equipment.

In another preferred embodiment, the defense sector may present unique opportunities for the application of the high-performance dielectric nanofluid in thermal management systems for military electronics, radar systems, and communication equipment that often operate in harsh environments with extreme temperature variations of from about −55 °C to about 125 °C. The nanofluid may be configured to be adapted to provide reliable cooling for these systems by adjusting its composition to withstand a wider range of operating conditions than typical commercial applications. In some preferred embodiments, the concentration of hBN nanoparticles may be increased to a range of from about 45% w/w to about 55% w/w to maximize thermal conductivity for high-power defense applications generating heat fluxes of from about 100 W/cm² to about 500 W/cm². The dielectric properties of the high-performance dielectric nanofluid, including electrical conductivity of less than about 1×10⁻⁹ S/m, may be particularly advantageous in cooling sensitive electronic warfare systems where electrical isolation is beneficial for maintaining signal integrity and preventing electromagnetic interference. By incorporating specialized additives at concentrations of from about 0.1% w/w to about 5% w/w or modifying the base fluid composition, the nanofluid may be engineered to resist chemical warfare agents or provide additional protection against electromagnetic interference in military environments operating at frequencies of from about 1 MHz to about 100 GHz. Optionally, the nanofluid formulation may include radiation-resistant additives for applications in space-based defense systems or nuclear environments where exposure to ionizing radiation is anticipated.

In a preferred embodiment, the high-performance dielectric nanofluid may find applications in advanced computing and telecommunications beyond traditional data centers, including cooling of 5G and future 6G network infrastructure where high-frequency components operating at frequencies of from about 24 GHz to about 300 GHz generate significant heat in compact spaces with power densities of from about 10 W/cm² to about 100 W/cm². By optimizing the viscosity within a range of from about 50 cSt to about 500 cSt and thermal properties of the high-performance dielectric nanofluid for these specific applications, more efficient and reliable cooling of base stations and network equipment may be achieved with flow rates of from about 0.1 liters per minute to about 10 liters per minute. In some instances, the nanofluid may be applied in intermediate cooling stages of quantum computing systems, where the high-performance dielectric nanofluid may be used to manage heat loads in the surrounding control electronics operating at temperatures of from about 4 K to about 300 K and cryogenic support systems. The nanofluid's low electrical conductivity of less than about 1×10⁻⁹ S/m and high thermal performance with thermal conductivity of at least about 1.0 W/m·K may contribute to the stability and reliability of these sensitive quantum computing environments where temperature fluctuations of less than about 0.1 K may be desirable. As illustrated in FIG. 2, the cooling system architecture may be adapted for telecommunications applications by scaling the cold plate dimensions and heat exchanger capacity to match the specific thermal loads of network infrastructure equipment.

In some preferred embodiments, the medical imaging industry may benefit from the application of the high-performance dielectric nanofluid in cooling high-performance equipment such as MRI machines operating with magnetic field strengths of from about 1.5 T to about 7 T, CT scanners with rotation speeds of from about 0.25 seconds to about 1 second per rotation, and PET scanners with detector arrays generating heat loads of from about 100 W to about 1000 W. These devices may generate substantial heat during operation and can benefit from precise temperature control to maintain image quality with spatial resolutions of from about 0.1 mm to about 1 mm and equipment longevity over operational lifetimes of from about 10 years to about 20 years. By adapting the nanofluid composition to meet the specific thermal management needs of medical imaging systems, the high-performance dielectric nanofluid may enable more compact and efficient cooling solutions with reduced footprints of from about 10% to about 50% compared to conventional air-cooled systems. In another preferred embodiment, the incorporation of biocompatible additives or the use of medical-grade PDMS as the base fluid 105 may be considered to help ensure compliance with healthcare regulations such as ISO 10993 biocompatibility standards. Optionally, the nanofluid formulation may be configured to meet specific regulatory requirements for medical device applications, including USP Class VI certification for the base fluid 105. The implementation of the high-performance dielectric nanofluid in medical imaging equipment cooling may result in improved image resolution, reduced scan times of from about 5% to about 25%, and increased equipment uptime of from about 95% to about 99.5%, potentially benefiting patient care and diagnostic capabilities in clinical settings.

As illustrated in FIG. 3, the present disclosure provides a method 300 for mixing the high-performance dielectric nanofluid that may be configured to produce a uniformly dispersed thermal management fluid suitable for electronic cooling applications. In a preferred embodiment, the method 300 begins at step 305, which indicates the initiation of the mixing process and may include preparatory activities such as equipment verification and component staging. Step 310 involves the precise measurement and combination of the base components, including the base fluid 105 and the hBN nanoparticles, where the PDMS may have a kinematic viscosity in the range of from about 50 cSt to about 500 cSt, with a preferred range of from about 100 cSt to about 150 cSt. In some preferred embodiments, the PDMS is first added to a clean, inert mixing vessel that may be constructed from materials such as stainless steel, glass, or fluoropolymer-lined containers to prevent contamination of the nanofluid formulation. The hBN nanoparticles may then be gradually introduced into the base fluid 105 over a period of from about 5 minutes to about 120 minutes while maintaining constant low-speed stirring at rotational speeds in the range of from about 50 rpm to about 500 rpm. This gradual addition can help to reduce agglomeration and may promote initial dispersion of the nanoparticles 110 throughout the base fluid volume, with the dispersant optionally being added either before, during, or after the hBN nanoparticle introduction depending on the specific formulation parameters.

In another preferred embodiment, once the primary components are combined, the mixture may undergo ultrasonic sonication during step 315 to further enhance nanoparticle dispersion and break down any remaining agglomerates that may have formed during the initial mixing stage. The sonication process may employ a high-power ultrasonic probe operating at a frequency in the range of from about 15 kHz to about 40 kHz, with a preferred frequency of approximately 20 kHz for PDMS-based nanofluid formulations. In some instances, the duration of sonication may vary depending on the batch size and desired dispersion quality, with typical durations ranging from about 10 minutes to about 60 minutes, and a preferred range of from about 20 minutes to about 30 minutes for batch sizes of from about 100 mL to about 10 L. The ultrasonic power density may be configured to be in the range of from about 20 W/L to about 500 W/L, which can provide sufficient energy input to disrupt nanoparticle agglomerates without causing degradation of the base fluid 105 or the hBN nanoparticles. Throughout the sonication process, temperature control may be maintained to preserve the integrity of the components and prevent thermal degradation, with a cooling system 215 such as a jacketed vessel, an ice bath, or a recirculating chiller being employed to keep the mixture temperature below approximately 30 °C, or alternatively below approximately 40 °C for formulations with enhanced thermal stability. As illustrated in FIG. 3, this temperature control during step 315 can help preserve the properties of the base fluid 105 and may prevent potential changes in the surface chemistry of the hBN nanoparticles that could otherwise affect dispersion stability.

Following the sonication step, the present disclosure provides for the introduction of additional components such as the anti-foam agent and thermal stabilizers during step 320, as illustrated in FIG. 3. In a preferred embodiment, these additives may be carefully measured and added while maintaining gentle stirring at rotational speeds in the range of from about 25 rpm to about 200 rpm to help ensure uniform distribution without introducing air bubbles into the nanofluid formulation. The anti-foam agent may be added at concentrations in the range of from about 1 ppm to about 1000 ppm, with a preferred range of from about 50 ppm to about 200 ppm for data center cooling applications where foam suppression during circulation is a consideration. In some preferred embodiments, the thermal stabilizers may be incorporated at concentrations in the range of from about 0.01% w/w to about 5% w/w, with a preferred range of from about 0.1% w/w to about 1% w/w for applications where sustained operation at elevated temperatures is anticipated. The incorporation of these components may be followed by a brief period of low-speed mixing for a duration of from about 5 minutes to about 30 minutes to promote homogenization throughout the nanofluid volume. Optionally, after the additives have been incorporated, the fluid may be allowed to rest for a specified period in the range of from about 15 minutes to about 24 hours to allow any entrapped air to escape and for the system to reach equilibrium before proceeding to subsequent processing steps.

In some preferred embodiments, quality control measures may be implemented throughout the mixing process during step 325 to help ensure consistency and performance of the high-performance dielectric nanofluid, as illustrated in FIG. 3. Periodic sampling may be conducted during and after the mixing process for various analyses, with sampling intervals in the range of from about every 5 minutes to about every 30 minutes depending on the batch size and process stage. In a preferred embodiment, particle size distribution measurements may be performed using dynamic light scattering techniques, laser diffraction methods, or nanoparticle tracking analysis to verify the dispersion state of the hBN nanoparticles, with target particle size distributions in the range of from about 50 nm to about 500 nm for the primary particle size. Viscosity measurements may be performed using a rheometer, a viscometer, or other suitable instrumentation to confirm that the fluid's flow properties meet the desired specifications, with target kinematic viscosity values in the range of from about 50 cSt to about 1000 cSt depending on the specific formulation and intended application. Thermal conductivity tests may be carried out using transient hot wire methods, laser flash analysis, or thermal probe techniques to assess the heat transfer capabilities of the mixture, with target thermal conductivity values of at least about 0.5 W/m·K, and preferably at least about 1.0 W/m·K for high-performance cooling applications. Alternatively, dielectric strength measurements may be performed in accordance with ASTM D149 to verify that the electrical insulation properties of the nanofluid meet specifications for direct-to-chip cooling applications.

The stability of the nanoparticle dispersion may be a factor in the performance of the high-performance dielectric nanofluid, and various assessment methods may be employed to characterize this property. In some instances, visual inspection may be conducted at various stages of the mixing process to check for any signs of settling, separation, or color changes that could indicate agglomeration or degradation of the nanofluid components. In a preferred embodiment, more advanced stability assessments may include zeta potential measurements using electrophoretic light scattering techniques to evaluate the electrostatic repulsion between particles, with zeta potential values in the range of from about −30 mV to about +30 mV, or alternatively outside this range, being indicative of different levels of dispersion stability. Accelerated stability tests, such as centrifugation at rotational speeds in the range of from about 1,000 rpm to about 20,000 rpm for durations of from about 10 minutes to about 60 minutes, may be performed on samples to predict the fluid's behavior under various conditions and over extended periods. In another preferred embodiment, temperature cycling tests involving exposure to temperatures in the range of from about −40 °C to about 150 °C for multiple cycles may be conducted to assess the stability of the nanofluid under thermal stress conditions representative of actual cooling system operation. These tests can help provide information regarding whether the nanoparticles 110 may remain well-dispersed during storage periods of from about 6 months to about 5 years and during operation in cooling systems over operational lifetimes of from about 1 year to about 10 years.

As illustrated in FIG. 3, step 330 involves filtration and packaging of the high-performance dielectric nanofluid to prepare the product for storage and distribution. In a preferred embodiment, the mixture may be passed through a series of filters with decreasing pore sizes, such as filters having pore sizes of approximately 25 μm, approximately 10 μm, approximately 5 μm, and approximately 1 μm in sequence, to remove any potential contaminants or oversized particles that could otherwise affect the performance of the nanofluid in cooling applications. This filtration step can help promote uniformity and purity of the final product, with target filtration efficiency of at least about 95% for particles larger than the specified pore size of the final filter stage. In some preferred embodiments, the filtered fluid may then undergo a final quality assurance check, which may include a comprehensive analysis of its thermal, electrical, and rheological properties to verify compliance with product specifications before release. Once approved, the high-performance dielectric nanofluid may be transferred to appropriate storage containers, such as airtight, inert vessels constructed from materials including high-density polyethylene, fluoropolymer-lined containers, or stainless steel drums with capacities in the range of from about 1 L to about 1000 L, to help prevent contamination and maintain the nanofluid properties until use. Proper labeling and documentation of batch information, including mixing parameters, quality control results, and manufacturing date, may be provided for traceability and consistency in production, with the method 300 proceeding to terminate at step 335 upon completion of the packaging and documentation activities.

As illustrated in FIG. 4, the present disclosure provides a manufacturing process for industrial production of the high-performance dielectric nanofluid that may be configured to achieve consistent product quality at production scale. In a preferred embodiment, the manufacturing process begins with a pre-dispersion preparation stage where hBN nanoparticles are combined with a low-viscosity PDMS having a kinematic viscosity in the range of from about 5 cSt to about 50 cSt to create a uniform suspension. The hBN nanoparticles may be carefully measured and added to the PDMS at a specific ratio, such as a ratio in the range of from about 30% w/w to about 60% w/w of the pre-dispersion, to achieve the desired concentration for subsequent processing. In some preferred embodiments, this mixture can undergo high-shear mixing at shear rates in the range of from about 1,000 s⁻¹ to about 50,000 s⁻¹ to break up agglomerates and promote even distribution of the nanoparticles 110 throughout the low-viscosity PDMS carrier. The pre-dispersion process may involve multiple mixing cycles, such as from about 2 cycles to about 10 cycles, with quality control checks performed between cycles to verify the consistency and stability of the suspension. In some instances, the pre-dispersion can serve as an intermediate product that facilitates the incorporation of hBN nanoparticles into the final formulation by providing a more manageable starting material for subsequent mixing operations.

In another preferred embodiment, following the pre-dispersion preparation, the base fluid 105 mixture may be prepared in a separate vessel as illustrated in FIG. 4. This step can involve combining high-viscosity PDMS having a kinematic viscosity in the range of from about 500 cSt to about 1000 cSt with medium-viscosity PDMS having a kinematic viscosity in the range of from about 100 cSt to about 500 cSt in predetermined proportions to achieve the desired rheological properties of the final product. In some preferred embodiments, the different viscosity grades of PDMS may be selected to balance flow characteristics, heat transfer capabilities, and long-term stability of the nanofluid, with blending ratios in the range of from about 20:80 to about 80:20 by weight depending on the target viscosity. The base fluid components can be mixed using controlled agitation at rotational speeds in the range of from about 50 rpm to about 300 rpm to promote homogeneity without introducing air bubbles or causing excessive shear that could degrade the polymer chains. Optionally, additional components such as thermal stabilizers at concentrations of from about 0.05% w/w to about 2% w/w may be incorporated into the base fluid mixture at this stage to provide thermal protection during subsequent processing steps. The preparation of the base fluid 105 can establish the foundational properties of the high-performance dielectric nanofluid, including the viscosity characteristics that influence pumping power and heat transfer performance in cooling applications.

As illustrated in FIG. 4, the present disclosure provides for a continuous flow microfluidic mixing stage that may be configured to achieve precise and controlled mixing of the pre-dispersion and base fluid components. In a preferred embodiment, this advanced mixing technique can allow for the achievement of a final hBN concentration of approximately 40% w/w in the nanofluid, with concentration tolerances of from about ±1% w/w to about ±5% w/w depending on the precision of the metering systems employed. The microfluidic device may employ a series of channels having characteristic widths in the range of from about 100 μm to about 2000 μm and mixing chambers designed to create controlled turbulence and enhance the dispersion of nanoparticles 110 within the flowing mixture. In some preferred embodiments, the pre-dispersion and base fluid 105 can be fed into separate inlets of the microfluidic device at flow rates in the range of from about 10 mL/min to about 1000 mL/min per inlet, where they undergo rapid and uniform mixing within residence times of from about 0.1 seconds to about 60 seconds. This method may provide advantages over traditional batch mixing, including improved consistency with batch-to-batch variation of less than about 5% for thermal conductivity measurements, reduced processing time of from about 50% to about 90% compared to batch processes, and the ability to fine-tune mixing parameters in real-time based on inline monitoring data. Alternatively, the microfluidic mixing stage can be configured with multiple parallel channels to increase throughput for high-volume production applications while maintaining the mixing quality achieved in single-channel configurations.

In a preferred embodiment, following the microfluidic mixing stage as illustrated in FIG. 4, the combined mixture may undergo in-line ultrasonic treatment that can be configured to further enhance the dispersion of hBN nanoparticles and break down remaining agglomerates. The ultrasonic treatment may be carefully controlled to maintain a temperature below approximately 30 °C throughout the process, or alternatively below approximately 40 °C for formulations with enhanced thermal stability additives. In some preferred embodiments, this temperature control can be achieved through the use of a cooling jacket, a heat exchanger integrated into the ultrasonic treatment zone, or other heat management systems capable of removing heat at rates of from about 100 W to about 10,000 W depending on the production throughput. The ultrasonic energy applied to the fluid, at frequencies in the range of from about 15 kHz to about 40 kHz and power densities of from about 20 W/L to about 500 W/L, may help to overcome van der Waals forces between nanoparticles 110, promoting a more stable and uniform dispersion throughout the nanofluid volume. In some instances, the duration of ultrasonic treatment can be optimized based on the residence time within the treatment zone, with typical exposure times in the range of from about 5 seconds to about 120 seconds for continuous flow configurations. The in-line ultrasonic treatment step may contribute to the long-term stability and performance of the high-performance dielectric nanofluid by reducing the presence of agglomerates that could otherwise settle during storage or cause flow restrictions in cooling system microchannels.

As illustrated in FIG. 4, the present disclosure provides for an additive injection stage where additives may be introduced to the treated mixture following the in-line ultrasonic treatment. In a preferred embodiment, these additives can include a dispersant at concentrations of from about 0.5% w/w to about 5% w/w for enhancing the long-term stability of the nanoparticle suspension, an anti-foam agent at concentrations of from about 10 ppm to about 500 ppm to suppress bubble formation during use, and thermal stabilizers at concentrations of from about 0.05% w/w to about 2% w/w to maintain the performance of the nanofluid across a wide temperature range. In some preferred embodiments, the additives may be introduced using precision dosing systems such as positive displacement pumps 220, mass flow controllers, or gravimetric feeders to achieve accurate and consistent incorporation into the mixture with dosing accuracy of from about ±0.5% to about ±5% of the target concentration. Optionally, corrosion inhibitors at concentrations of from about 100 ppm to about 2000 ppm and biocides at concentrations of from about 50 ppm to about 500 ppm may be added at this stage depending on the intended application and storage requirements of the final product. In another preferred embodiment, the addition of these components can be followed by a brief mixing or homogenization step using static mixers or low-shear agitation for residence times of from about 10 seconds to about 300 seconds to promote uniform distribution throughout the nanofluid. The careful selection and addition of these additives may contribute to the overall performance and reliability of the high-performance dielectric nanofluid product in electronic cooling applications.

In a preferred embodiment, to complete the manufacturing process as illustrated in FIG. 4, the high-performance dielectric nanofluid may undergo a series of filtration stages that can be configured to remove potential contaminants, oversized particles, or agglomerates that may have formed during the production process. The filtration system can employ a series of filters with progressively finer pore sizes, such as a first filter having a pore size of approximately 25 μm, a second filter having a pore size of approximately 10 μm, and a third filter having a pore size of approximately 1μm to approximately 5 μm, to provide thorough purification of the nanofluid. In some preferred embodiments, inline particle size analysis using dynamic light scattering or laser diffraction techniques and quality control checks may be performed during or after the filtration process to verify that the final product meets specifications including particle size distribution with D90 values below approximately 500 nm and absence of agglomerates larger than approximately 10 μm. The filtration stages may be configured with filter housings capable of accommodating filter elements with surface areas in the range of from about 0.1 m² to about 10 m² depending on the production throughput and the particulate loading of the incoming stream. In some instances, the filtered high-performance dielectric nanofluid can then be transferred to storage containers or packaging systems constructed from inert materials such as high-density polyethylene, fluoropolymer-lined drums, or stainless steel vessels with capacities in the range of from about 1 L to about 1000 L. Alternatively, the filtration stages may include provisions for filter integrity testing and automated filter changeout to maintain consistent product quality during extended production campaigns, with the final filtration step helping to promote the consistency and quality of the high-performance dielectric nanofluid product for various cooling applications.

### Example 1 (Prophetic)—Nanofluid at Approximately 40% w/w hBN Loading

In a preferred embodiment, the present disclosure provides a dielectric nanofluid that may be configured to achieve enhanced thermal management performance for electronic cooling applications. The preparation of this nanofluid can begin with charging a clean, inert mixing vessel with approximately 600 g of polydimethylsiloxane (PDMS) having a kinematic viscosity at 25 °C of approximately 100 cSt. In some instances, the PDMS may be selected from commercially available grades such as Dow Xiameter PMX-200 100 cSt silicone fluid, or alternatively, an equivalent grade from suppliers including Gelest, Momentive, or Shin-Etsu may be employed. The mixing vessel may be constructed from materials such as stainless steel, glass, or fluoropolymer-lined containers to help prevent contamination of the nanofluid formulation during preparation. As illustrated in FIG. 3, the method 300 for mixing the thermal management fluid begins at step 305 and proceeds through a series of controlled processing stages. The selection of the appropriate PDMS grade can influence the final rheological properties and thermal performance characteristics of the resulting nanofluid.

In some preferred embodiments, approximately 400 g of hBN nanoparticles may be added to the base fluid 105 to achieve a target loading of approximately 40% w/w in the combined mixture. The hBN nanoparticles can be selected from commercial grades such as Momentive PolarTherm PT120, 3M Boron Nitride Cooling Filler, or an equivalent grade having a primary particle size in the range of approximately 100 nm to approximately 250 nm and exhibiting a platelet morphology. As illustrated in FIG. 3, step 310 involves the precise measurement and combination of the base components, where the hBN nanoparticles may be added to the vessel gradually over a period of from about 15 to about 60 minutes under low-shear stirring at about 100-300 rpm. This gradual addition approach can help reduce agglomeration and may promote initial dispersion of the nanoparticles 110 throughout the base fluid volume. In some instances, the stirring speed may be adjusted within the specified range based on the observed incorporation behavior of the nanoparticles 110 into the PDMS. The platelet morphology of the hBN nanoparticles may contribute to anisotropic thermal conductivity enhancement in the resulting nanofluid formulation.

In another preferred embodiment, a siloxane-compatible dispersant may be incorporated into the nanofluid formulation to provide steric stabilization of the suspended hBN nanoparticles. The dispersant can be selected from materials functionally equivalent to Dow Corning Q2-5211, and may be used at a concentration of approximately 1% to approximately 2% w/w of the final nanofluid. As illustrated in FIG. 1, the dispersant molecules can adsorb onto the surface of the hBN nanoparticles and extend polymer chains into the surrounding PDMS medium, creating a physical barrier that maintains separation between individual particles in the fluid. In some instances, the dispersant may be added during the hBN introduction stage, while alternatively, the dispersant can be incorporated after the nanoparticles 110 have been initially wetted by the base fluid 105. The timing of dispersant addition may be configured to optimize the wetting and distribution of the hBN nanoparticles within the formulation. The molecular architecture of the dispersant can influence the thickness of the steric barrier formed around each nanoparticle, which may affect the long-term stability of the suspension during storage and operation.

In a preferred embodiment, the combined mixture may be subjected to ultrasonic treatment to further enhance nanoparticle dispersion and break down residual agglomerates that may have formed during the initial mixing stage. As illustrated in FIG. 3, step 315 involves ultrasonic sonication using a high-power ultrasonic probe operating at a frequency of approximately 20 kHz for a period of from about 20 to about 30 minutes. During the ultrasonic treatment, the mixture temperature may be maintained at or below approximately 30 °C by way of a cooling jacket, an ice bath, or an equivalent heat-management arrangement to preserve the integrity of the components and prevent thermal degradation. In some preferred embodiments, the ultrasonic power density may be configured to be in the range of from about 20 W/L to about 500 W/L, which can provide sufficient energy input to disrupt nanoparticle agglomerates without causing degradation of the base fluid 105 or the hBN nanoparticles. The ultrasonic treatment can help overcome van der Waals forces between nanoparticles 110, promoting a more stable and uniform dispersion throughout the nanofluid volume. Optionally, the duration of ultrasonic treatment may be adjusted based on the batch size and the observed dispersion quality as assessed by periodic sampling during the process.

In some preferred embodiments, additional additives may be incorporated into the nanofluid formulation following the ultrasonic treatment stage to enhance performance and long-term stability. As illustrated in FIG. 3, step 320 involves the introduction of components such as an anti-foam agent (for example, a silicone-based defoamer) at approximately 50-200 ppm, a thermal stabilizer (for example, a hindered phenol or a hindered amine) at approximately 0.1% to approximately 1% w/w, a corrosion inhibitor (for example, sodium molybdate) at approximately 250-1000 ppm, and a biocide (for example, 1,2-Benzisothiazol-3(2H)-one) at approximately 100-300 ppm. These additives can be added to the mixture under gentle stirring at rotational speeds in the range of from about 25 rpm to about 200 rpm to help ensure uniform distribution without introducing air bubbles into the nanofluid formulation. In some instances, the mixture may be allowed to rest for a period sufficient for entrapped air to escape before proceeding to subsequent processing steps. Alternatively, the order of additive incorporation may be adjusted based on compatibility considerations and the specific formulation requirements. The selection of specific additive types and concentrations can depend on factors including the intended operating conditions, storage requirements, and the materials of construction in the cooling system 215 where the nanofluid will be employed.

In another preferred embodiment, the nanofluid may undergo filtration to remove any residual agglomerates, contaminants, or oversized particles that could otherwise affect performance in cooling applications. As illustrated in FIG. 3, step 330 involves passing the mixture through a series of filters having progressively decreasing pore sizes, such as filter pore sizes of about 10 μm, about 5 μm, and about 1 μm in sequence. This multi-stage filtration approach can help promote uniformity and purity of the final product, with target filtration efficiency of at least about 95% for particles larger than the specified pore size of the final filter stage. In some preferred embodiments, quality control measures may be implemented during step 325 to verify that the nanofluid properties meet desired specifications, including particle size distribution measurements, viscosity measurements, and thermal conductivity tests. Based on the thermal conductivity of hBN (reported in the literature as approximately 200-400 W/m·K in-plane) and on Maxwell-Garnett-type effective-medium predictions for platelet-filled polymer systems at approximately 40% w/w loading, the dielectric nanofluid prepared according to this prophetic example can be expected to exhibit a thermal conductivity of at least about 1.0 W/m·K when measured by the transient hot-wire method. Additionally, the nanofluid may be expected to exhibit a dielectric strength of at least about 15 kV/mm when measured in accordance with ASTM D149, and an electrical conductivity of less than about 1×10⁻⁹ S/m when measured in accordance with ASTM D1169, which can provide suitable electrical isolation characteristics for direct-to-chip cooling applications in data center environments.

### Example 2 (Prophetic)—Continuous-Flow Industrial Production

In a preferred embodiment, the present disclosure provides a method for preparing a dielectric nanofluid at production scale using continuous-flow processing techniques. As illustrated in FIG. 4, the manufacturing process may be configured to achieve consistent product quality while enabling higher throughput compared to batch processing methods. The process begins with the preparation of a pre-dispersion by combining hBN nanoparticles having a primary particle size in the range of approximately 100 nm to approximately 250 nm with a first, lower-viscosity PDMS grade having a kinematic viscosity at 25 °C of approximately 20 cSt. In some instances, the hBN nanoparticles may be selected from commercial grades such as Momentive PolarTherm PT120, 3M Boron Nitride Cooling Filler, or equivalent grades exhibiting platelet morphology suitable for thermal management applications. The pre-dispersion can be prepared under high-shear mixing at shear rates in the range of from about 1,000 s⁻¹ to about 50,000 s⁻¹ to produce a uniform suspension of the nanoparticles 110 within the low-viscosity PDMS carrier. This pre-dispersion stage may facilitate subsequent incorporation of the hBN nanoparticles into the final formulation by providing a more manageable intermediate product with improved dispersion characteristics.

In another preferred embodiment, a base fluid 105 mixture may be prepared separately by blending multiple PDMS grades to achieve desired rheological properties for the final nanofluid product. The base fluid 105 mixture can comprise a first PDMS grade having a kinematic viscosity of approximately 100 cSt blended with a second PDMS grade having a kinematic viscosity of approximately 500 cSt. In some preferred embodiments, the proportions of the first and second PDMS grades may be selected to yield a target kinematic viscosity of approximately 150 cSt in the blended base fluid 105 mixture. The blending approach can provide flexibility in tailoring the viscosity characteristics of the base fluid 105 to specific application requirements while maintaining compatibility with the pre-dispersion. As illustrated in FIG. 4, the base fluid 105 preparation stage may occur in parallel with the pre-dispersion preparation, allowing for efficient utilization of production equipment and reduced overall processing time. Optionally, thermal stabilizers or other additives may be incorporated into the base fluid 105 mixture at this stage to provide thermal protection during subsequent processing steps.

In some preferred embodiments, the pre-dispersion and the base fluid mixture may be introduced into separate inlets of a continuous-flow microfluidic mixing device to achieve controlled and uniform combination of the components. The microfluidic mixing device can comprise mixing channels having a characteristic width in the range of approximately 200 μm to approximately 1000 μm, which may provide favorable mixing conditions while accommodating the viscosity characteristics of the incoming streams. As illustrated in FIG. 4, the microfluidic mixing stage can enable precise control over the combination of the pre-dispersion and base fluid mixture through controlled flow rates and residence times within the mixing channels. In some instances, the flow rates of the pre-dispersion and base fluid mixture may be selected to yield a final hBN concentration of approximately 40% w/w in the combined mixture exiting the microfluidic device. The continuous-flow configuration may provide advantages over traditional batch mixing, including improved consistency with batch-to-batch variation of less than about 5% for thermal conductivity measurements and reduced processing time compared to batch processes. Alternatively, the microfluidic mixing device can be configured with multiple parallel channels to increase throughput for high-volume production applications while maintaining the mixing quality achieved in single-channel configurations.

In a preferred embodiment, the combined mixture exiting the microfluidic device may be subjected to in-line ultrasonic treatment to further enhance the dispersion of hBN nanoparticles and break down residual agglomerates that may have formed during the mixing process. The in-line ultrasonic treatment can be performed at an ultrasonic frequency of approximately 20 kHz and at a volumetric power density in the range of approximately 50 W/L to approximately 500 W/L. In some instances, the ultrasonic energy applied to the flowing mixture may help overcome van der Waals forces between nanoparticles 110, promoting a more stable and uniform dispersion throughout the nanofluid volume. The combined mixture may be maintained at a temperature at or below approximately 30 °C during the in-line ultrasonic treatment by a cooling jacket, a heat exchanger integrated into the ultrasonic treatment zone, or an equivalent heat-management arrangement capable of removing heat at rates sufficient to maintain the target temperature. As illustrated in FIG. 4, the in-line ultrasonic treatment stage can be positioned downstream of the microfluidic mixing stage to provide additional dispersion enhancement before additive incorporation. This temperature control during ultrasonic treatment can help preserve the properties of the base fluid 105 and may prevent potential changes in the surface chemistry of the hBN nanoparticles that could otherwise affect dispersion stability.

In some preferred embodiments, the dispersant, anti-foam agent, thermal stabilizer, corrosion inhibitor, and biocide may be introduced downstream of the in-line ultrasonic treatment by precision-dosing pumps 220 to achieve accurate and consistent incorporation into the mixture. As illustrated in FIG. 4, the additive injection stage can be positioned after the ultrasonic treatment to allow for controlled introduction of the various additives into the processed mixture. The precision-dosing pumps 220 may comprise positive displacement pumps 220, mass flow controllers, or gravimetric feeders capable of achieving dosing accuracy of from about ±0.5% to about ±5% of the target concentration for each additive. In some instances, the dispersant may be added at concentrations of from about 0.5% w/w to about 5% w/w, the anti-foam agent at concentrations of from about 10 ppm to about 500 ppm, the thermal stabilizer at concentrations of from about 0.05% w/w to about 2% w/w, the corrosion inhibitor at concentrations of from about 100 ppm to about 2000 ppm, and the biocide at concentrations of from about 50 ppm to about 500 ppm. Optionally, the order of additive introduction may be adjusted based on compatibility considerations and the specific formulation requirements for the intended application. The careful selection and controlled addition of these additives may contribute to the overall performance and reliability of the high-performance dielectric nanofluid product in electronic cooling applications.

In another preferred embodiment, the resulting dielectric nanofluid may be filtered in line through one or more filters having progressively decreasing pore sizes to remove potential contaminants, oversized particles, or agglomerates that may have formed during the production process. As illustrated in FIG. 4, the filtration stages can be positioned downstream of the additive injection stage to provide thorough purification of the nanofluid before transfer to storage containers. In some preferred embodiments, the filtration system may employ a first filter having a pore size of approximately 25 μm, a second filter having a pore size of approximately 10 μm, and a third filter having a pore size of approximately 1 μm to approximately 5 μm in sequence. The filtered dielectric nanofluid can then be transferred to inert storage containers constructed from materials such as high-density polyethylene, fluoropolymer-lined drums, or stainless steel vessels to help prevent contamination and maintain the nanofluid properties until use. In some instances, inline particle size analysis using dynamic light scattering or laser diffraction techniques may be performed during or after the filtration process to verify that the final product meets specifications including particle size distribution with D90 values below approximately 500 nm. The dielectric nanofluid prepared according to this prophetic example may be expected to exhibit property values within the ranges set forth in Example 1, including a thermal conductivity of at least about 1.0 W/m·K, a dielectric strength of at least about 15 kV/mm when measured in accordance with ASTM D149, and an electrical conductivity of less than about 1×10⁻⁹ S/m when measured in accordance with ASTM D1169.

### Example 3 (Prophetic)—Cooling System Operation

In a preferred embodiment, the present disclosure provides a cooling system 215 that may be configured to provide thermal management for electronic components in data center and high-performance computing environments. As illustrated in FIG. 2, the cooling system 215 can comprise a server rack 205 housing one or more heat-generating processors, one or more cold plates 206 positioned in thermal contact with the processors, a coolant distribution unit containing one or more pumps 220, and one or more heat exchangers 210 fluidly coupled to the coolant distribution unit. The dielectric nanofluid prepared according to Example 1 or Example 2 may serve as the coolant circulating through the cooling system 215 to absorb and transport thermal energy away from the electronic components. In some preferred embodiments, the server rack 205 may be configured to house multiple servers arranged vertically, with each server containing processors and other electronic components that generate thermal loads during operation. The cold plates 206 can be attached to or positioned adjacent to the heat-generating elements and may be designed to efficiently absorb and transfer thermal energy from the electronic components to the circulating dielectric nanofluid. The coolant distribution unit may serve as a central hub for managing the circulation of the dielectric nanofluid throughout the cooling circuit, and can include flow control mechanisms and monitoring instrumentation to maintain optimal cooling performance.

In another preferred embodiment, the coolant distribution unit may be configured to circulate the dielectric nanofluid through the one or more cold plates 206 at a flow rate selected to maintain the processors at an operational junction temperature within manufacturer-specified limits. The flow rate can be adjusted based on the thermal load of the electronic components, the thermal conductivity of the dielectric nanofluid, and the design characteristics of the cold plates 206 to achieve optimal heat removal performance. In some instances, the coolant distribution unit may include variable-speed pumps 220 or electronically actuated valves to adjust the nanofluid circulation rate based on real-time thermal load demands detected by temperature sensors positioned throughout the system. As illustrated in FIG. 2, the dielectric nanofluid flows from the coolant distribution unit through insulated pipes or tubing to the cold plates 206 attached to the servers within the rack, where the insulation may help minimize thermal losses during transit. The flow rate may be configured to be in the range of from about 0.5 liters per minute to about 50 liters per minute per cold plate, depending on the thermal load requirements and system configuration. Optionally, the cooling system 215 may include redundant pumps 220 to provide backup circulation capacity in the event of component maintenance or failure.

In some preferred embodiments, during steady-state operation, the dielectric nanofluid may enter the one or more cold plates 206 at a temperature of approximately 25 °C to approximately 40 °C, with a preferred inlet temperature of approximately 35 °C for data center applications. As the dielectric nanofluid flows through channels, passages, or microstructures within the cold plates 206, it can come into close thermal contact with the heat-generating electronic components to facilitate heat absorption. The dielectric nanofluid may exit the one or more cold plates 206 at a temperature of approximately 45 °C to approximately 60 °C, with a preferred outlet temperature of approximately 50 °C for typical data center operating conditions. This temperature differential defines a nominal temperature rise of approximately 10 °C to approximately 25 °C across the cold plates 206, which can demonstrate the heat absorption capacity of the dielectric nanofluid during circulation. In some instances, the cold plate channels may have characteristic dimensions in the range of from about 0.1 mm to about 10 mm, which can be selected to balance heat transfer performance with pressure drop considerations. Alternatively, the cold plates 206 may be engineered with micro-channel structures, pin-fin arrays, or enhanced surface geometries to maximize heat transfer from the electronic components to the dielectric nanofluid.

In a preferred embodiment, downstream of the cold plates 206, the dielectric nanofluid may pass through the one or more heat exchangers 210, which can be configured to transfer heat from the dielectric nanofluid to a secondary cooling medium. As illustrated in FIG. 2, the heat exchangers 210 may facilitate the transfer of thermal energy from the dielectric nanofluid to a secondary cooling medium, which can comprise facility water, chilled water, ambient air, or another liquid coolant depending on the available infrastructure. The heat exchangers 210 can be configured as liquid-to-liquid heat exchangers 210, liquid-to-air heat exchangers 210, or combinations thereof depending on the specific installation requirements and available facility infrastructure. In some preferred embodiments, the heat exchange process can effectively lower the temperature of the dielectric nanofluid by an amount in the range of from about 10 °C to about 30 °C, preparing it for recirculation through the cold plates 206. The dielectric nanofluid may return to the coolant distribution unit at a temperature of approximately 20 °C to approximately 35 °C, ready for recirculation through the system. Optionally, the cooling system 215 may include redundant heat exchangers 210 to provide backup cooling capacity in the event of component maintenance or failure.

In some preferred embodiments, based on the reported thermal conductivity of the dielectric nanofluid of at least about 1.0 W/m·K and a representative specific heat capacity for PDMS-based fluids of approximately 1.5 kJ/kg·K to approximately 1.7 kJ/kg·K for neat PDMS, the cooling system 215 may be expected to support direct-to-chip cooling of server processors at thermal design power levels consistent with high-density computing workloads. The dielectric nanofluid prepared according to Example 1 or Example 2 can be expected to fall within a similar order of magnitude for specific heat capacity, which may provide favorable heat absorption characteristics for electronic cooling applications. In some instances, observed heat-removal performance may depend on factors including cold-plate geometry, flow rate, secondary-loop temperature, and the specific thermal load of the electronic components being cooled. As illustrated in FIG. 2, the closed-loop nature of the cooling system 215 can help prevent contamination of the dielectric nanofluid and may contribute to maintaining its performance characteristics over extended periods of operation. The dielectric properties of the PDMS-based nanofluid, including a dielectric strength exceeding about 15 kV/mm and an electrical conductivity of less than about 1×10⁻⁹ S/m, can provide an added layer of safety, as the fluid may come into direct contact with electronic components without risk of electrical short circuits or component damage. Alternatively, the cooling system 215 configuration may be adapted for different applications by scaling the cold plate dimensions, heat exchanger capacity, and flow rates to match the specific thermal loads of the electronic equipment being cooled.

In another preferred embodiment, the cooling system 215 may include monitoring and control features configured to optimize the performance of the dielectric nanofluid during operation. Sensors positioned throughout the system may monitor temperatures, flow rates, and pressure differentials, allowing for dynamic adjustments to maintain optimal cooling performance during varying workload conditions. In some instances, the cooling system 215 may include filtration components configured to remove particulates that could potentially accumulate over time, which can help ensure the long-term stability and performance of the dielectric nanofluid during extended operation. The filtration components may comprise filters with pore sizes in the range of from about 1 μm to about 25 μm, which can capture agglomerates or contaminants while permitting the dispersed hBN nanoparticles to pass through. Optionally, the cooling system 215 may include provisions for online monitoring of nanofluid properties, such as viscosity sensors or particle counters, to provide real-time assessment of fluid condition and enable predictive maintenance scheduling. The combination of enhanced thermal conductivity, dielectric properties, and long-term stability of the dielectric nanofluid may enable higher computational densities and improved energy efficiency compared to conventional cooling approaches in data center environments.

The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For instance, the implementations described above can be directed to various combinations and subcombinations of the disclosed features and/or combinations and subcombinations of several further features disclosed above. In addition, the logic flow depicted in the accompanying figures and/or described herein do not necessarily require the particular order shown, or sequential order, to achieve desirable results. It will be readily understood to those skilled in the art that various other changes in the details, devices, and arrangements of the parts and method stages which have been described and illustrated in order to explain the nature of this inventive subject matter can be made without departing from the principles and scope of the inventive subject matter.

1. A dielectric nanofluid for electronic cooling, comprising:
a base fluid comprising polydimethylsiloxane (PDMS);
hexagonal boron nitride (hBN) nanoparticles dispersed within the base fluid at a concentration of at least 20% w/w;
a dispersant configured to provide steric stabilization of the hBN nanoparticles within the base fluid;
an anti-foam agent; and
a thermal stabilizer.

2. The dielectric nanofluid of claim 1, wherein the hBN nanoparticles are present at a concentration of from about 25% w/w to about 55% w/w.

3. The dielectric nanofluid of claim 2, wherein the hBN nanoparticles are present at a concentration of from about 35% w/w to about 45% w/w.

4. The dielectric nanofluid of claim 3, wherein the hBN nanoparticles are present at a concentration of about 40% w/w.

5. The dielectric nanofluid of claim 1, wherein the hBN nanoparticles have a primary particle size in the range of from about 50 nm to about 1000 nm.

6. The dielectric nanofluid of claim 5, wherein the hBN nanoparticles have a primary particle size in the range of from about 50 nm to about 500 nm.

7. The dielectric nanofluid of claim 6, wherein the hBN nanoparticles have a primary particle size in the range of from about 100 nm to about 250 nm and a platelet morphology having an aspect ratio of from about 5 to about 50.

8. The dielectric nanofluid of claim 1, wherein the hBN nanoparticles are surface-functionalized with a silane coupling agent.

9. The dielectric nanofluid of claim 8, wherein the silane coupling agent is selected from the group consisting of (3-aminopropyl)triethoxysilane (APTES), octyltriethoxysilane (OTES), a fluorosilane, and combinations thereof.

10. The dielectric nanofluid of claim 1, wherein the PDMS has a kinematic viscosity at 25 °C in the range of from about 50 cSt to about 1000 cSt.

11. The dielectric nanofluid of claim 10, wherein the PDMS has a kinematic viscosity at 25 °C in the range of from about 100 cSt to about 150 cSt.

12. The dielectric nanofluid of claim 1, wherein the nanofluid has a thermal conductivity of at least about 1.0 W/m·K when measured by the transient hot-wire method, and a dielectric strength of at least about 15 kV/mm when measured in accordance with ASTM D149.

13. The dielectric nanofluid of claim 1, further comprising a corrosion inhibitor and a biocide.

14. A method of manufacturing the dielectric nanofluid of claim 1, comprising:
preparing a pre-dispersion comprising hBN nanoparticles suspended in a first portion of PDMS having a first viscosity;
preparing a base fluid mixture comprising a second portion of PDMS having a second viscosity different from the first viscosity;
combining the pre-dispersion and the base fluid mixture in a continuous-flow microfluidic device to form a combined mixture;
subjecting the combined mixture to in-line ultrasonic treatment while maintaining the combined mixture at a temperature at or below about 30 °C; and
introducing the dispersant, the anti-foam agent, and the thermal stabilizer into the combined mixture after the in-line ultrasonic treatment.

15. The method of claim 14, wherein the in-line ultrasonic treatment is carried out at an ultrasonic frequency in the range of from about 15 kHz to about 40 kHz and at a volumetric power density in the range of from about 50 W/L to about 500 W/L.

16. The method of claim 15, wherein the in-line ultrasonic treatment is carried out at an ultrasonic frequency of about 20 kHz.

17. The method of claim 14, wherein the continuous-flow microfluidic device comprises one or more mixing channels having a characteristic width in the range of from about 100 μm to about 2000 μm.

18. The method of claim 14, wherein the first viscosity is in the range of from about 10 cSt to about 100 cSt and the second viscosity is in the range of from about 100 cSt to about 1000 cSt.

19. The method of claim 14, further comprising filtering the combined mixture through one or more filters having progressively decreasing pore sizes to produce a filtered nanofluid.

20. The method of claim 14, wherein at least a portion of the hBN nanoparticles are surface-functionalized with a silane coupling agent prior to the preparing of the pre-dispersion.

21. The method of claim 14, wherein the combined mixture is formed at a final hBN concentration of about 40% w/w.

22. A cooling system for electronic components, comprising:
a server rack configured to house one or more heat-generating electronic components;
one or more cold plates in thermal contact with the one or more heat-generating electronic components;
a coolant distribution unit fluidly coupled to the one or more cold plates and configured to circulate a coolant through the one or more cold plates;
one or more heat exchangers fluidly coupled to the coolant distribution unit and configured to remove heat from the coolant; and
the dielectric nanofluid of claim 1 as the coolant.

23. The cooling system of claim 22, wherein the coolant distribution unit is configured to circulate the dielectric nanofluid such that the dielectric nanofluid enters the one or more cold plates at a temperature in the range of from about 25 °C to about 40 °C and exits the one or more cold plates at a temperature in the range of from about 45 °C to about 60 °C during steady-state operation.

24. The cooling system of claim 22, wherein the one or more cold plates comprise micro-channel structures configured to increase thermal contact area with the dielectric nanofluid.

25. The cooling system of claim 22, further comprising one or more pumps associated with the coolant distribution unit and one or more filters configured to remove particulates from the dielectric nanofluid during circulation.

26. The cooling system of claim 22, further comprising one or more sensors configured to monitor one or more of temperature, flow rate, and pressure of the dielectric nanofluid during circulation.

27. A method of cooling an electronic component, comprising:
providing the dielectric nanofluid of claim 1;
circulating the dielectric nanofluid in thermal contact with the electronic component; and
removing heat from the dielectric nanofluid downstream of the electronic component.

28. The method of claim 27, wherein the electronic component comprises a processor housed within a server rack, and wherein the dielectric nanofluid is circulated through a cold plate in thermal contact with the processor.
